(19) United States
(12) Patent Application Publication
(10) Pub. No.: US 2022/0018011 A1
(43) Pub. Date: Jan. 20, 2022

(54) MASK ASSEMBLY AND METHOD OF PROVIDING MASK ASSEMBLY

(71) Applicant: Samsung Display Co., LTD., Yongin-si (KR)

(72) Inventors: JUNHYEUK KO, Yongin-si (KR); BYUNG IK KONG, Asan-si (KR); SEIL KIM, Hwaseong-si (KR); EUIGYU KIM, Suwon-si (KR); SOOHYUN MIN, Asan-si (KR); SANG MIN YI, Suwon-si (KR); WONYOUNG JANG, Hwaseong-si (KR); SEUNGJU HONG, Yongin-si (KR)

(21) Appl. No.: 17/195,771

(22) Filed: Mar. 9, 2021

(30) Foreign Application Priority Data
Jul. 14, 2020 (KR) 10-2020-0086881

(51) Int. Cl. C23C 14/04; C23C 16/04

(52) U.S. Cl. CPC C23C 14/042; H01L 51/0011; C23C 16/042

(57) ABSTRACT

A mask assembly includes a mask frame including an edge portion including opposing upper and lower portions along a first direction, and a support which between the upper portion and the lower portion of the edge portion along the first direction; and a mask attachable to the mask frame. The mask includes a pattern area corresponding to the support and including a first welded area at which the mask is attachable to the support, an alignment adjustment pattern adjacent to the first welded area along the first direction, and a second thickness of the mask at the alignment adjustment pattern which is less than a first thickness of the mask at the first welded area, and a first deposition area including upper deposition openings of the mask and between the upper portion and the support of the mask frame.

This application claims priority to Korean Patent Application No. 10-2020-0086881 filed on Jul. 14, 2020, and all the benefits accruing therefrom under 35 U.S.C. § 119, the entire disclosure of which is incorporated herein by reference.

### BACKGROUND

### 1. Field

Embodiments relate generally to a mask assembly and a method of manufacturing a mask assembly. More particularly, embodiments relate to openings defined in a mask assembly and a method of providing a mask assembly having the openings therein.

### 2. Description of the Related Art

Flat panel display devices are used as display devices for replacing a cathode ray tube display device due to lightweight and thin characteristics thereof. As representative examples of such flat panel display devices, there are a liquid crystal display device and an organic light emitting diode display device.

In order to provide the display device, components included in the display device may be provided or formed on a mother substrate. In a process of providing an organic light emitting diode display device, a fine metal mask may be used to deposit organic light emitting layers of a mother substrate among components of the organic light emitting diode display device. A plurality of openings through which a deposition material passes may be provided or formed in the fine metal mask. The openings may be located to correspond to sub-pixel areas (e.g., areas in which the organic light emitting layer is provided) of the organic light emitting diode display device.

### SUMMARY

As a mother substrate becomes larger, a deposition mask may be provided to have a relatively long length. In a process of providing or forming deposition openings in the relatively long deposition mask, the deposition openings may not be provided or formed in a single process, so that upper deposition openings in an upper portion of the deposition mask and lower deposition openings in a lower portion of the deposition mask are provided at different times, in different processes, etc. However, when some of the deposition openings are provided or formed in the upper portion of the deposition mask and then the remainder of the deposition openings are provided or formed in the lower portion of the deposition mask, the deposition openings in the lower portion of the deposition mask may not accurately overlap corresponding lower sub-pixel areas of the mother substrate, so that organic light emitting layers (e.g., deposition pattern) may not be accurately provided or formed in the corresponding sub-pixel areas, respectively.

Embodiments provide a mask assembly including deposition openings.

Embodiments provide a method of providing or manufacturing a mask assembly including deposition openings.

According to an embodiment, a mask assembly includes a deposition mask frame including an edge portion including an upper portion and a lower portion opposing each other along a first direction, and a support which is extended along a second direction crossing the first direction and is between the upper portion and the lower portion of the edge portion along the first direction, and a deposition mask extending along the first direction and attachable to the deposition mask frame, the deposition mask including a pattern area corresponding to the support of the deposition mask frame, the pattern area including a first welded area at which the deposition mask is attachable to the support, an alignment adjustment pattern which is adjacent to the first welded area along the first direction and corresponds to the support, a first thickness of the deposition mask at the first welded area, and a second thickness of the deposition mask at the alignment adjustment pattern which is less than the first thickness, and a first deposition area including upper deposition openings of the deposition mask, the first deposition area between the upper portion and the support of the deposition mask frame.

In an embodiment, the alignment adjustment pattern may include a groove.

In an embodiment, the groove may be provided in plural including a plurality of grooves spaced apart from each other along the second direction.

In an embodiment, the alignment adjustment pattern may include a through-opening.

In an embodiment, a top surface of the support may be exposed to outside the deposition mask by the through-opening of the alignment adjustment pattern.

In an embodiment, a deposition material may not pass through the through-opening.

In an embodiment, the through-opening may be provided in plural including a plurality of through-openings spaced apart from each other in the second direction.

In an embodiment, the deposition mask may further include a second welded area at which the deposition mask is attachable to the support of the deposition mask frame.

In an embodiment, the alignment adjustment pattern may be between the first welded area and the second welded area.

In an embodiment, the deposition mask which is attached to the deposition mask frame may be attached to the support at both the first welded area and the second welded area and may be unattached from the support at the alignment adjustment pattern.

In an embodiment, the mask may further include a second deposition area including lower deposition openings.

In an embodiment, the pattern area may be between the first deposition area and the second deposition area.

In an embodiment, a deposition material may pass through the upper and lower openings in the first and second deposition areas, respectively.

In an embodiment, the mask may further include a first fixing area, a second fixing area, a third welded area which is in the first fixing area and at which the deposition mask is attachable to the upper portion of the deposition mask frame and a fourth welded area which is in the second fixing area and at which the deposition mask is attachable to the lower portion of the deposition mask frame.

In an embodiment, the first deposition area, the pattern area and the second deposition area may be between the first fixing area and the second fixing area.

In an embodiment, the first and second fixing areas may overlap the edge portion.

In an embodiment, the deposition mask which is attached to the deposition mask frame at the third welded area and the first welded area fixes a position of the upper deposition openings in the first deposition area relative to the deposition mask frame, and the deposition mask which is attached to the deposition mask frame at the second welded area and the fourth welded area fixes a position of the lower deposition openings in the second deposition area relative to the deposition mask frame.

According to an embodiment, a method of providing a mask assembly includes providing a mask frame including an edge portion including an upper portion and a lower portion opposing each other along a first direction, and a support which is extended along a second direction crossing the first direction and is between the upper portion and the lower portion of the edge portion along the first direction, providing a mother substrate including a plurality of sub-pixel areas, facing the mask frame, providing a deposition mask facing the mother substrate with the mask frame therebetween, the deposition mask which faces the mother substrate including in order along the first direction a first fixing area corresponding to the upper portion of the mask frame, a first deposition area corresponding to upper sub-pixel areas of the mother substrate and including upper deposition openings, a pattern area corresponding to the support of the mask frame and including an alignment adjustment pattern, where a thickness of the deposition mask at the alignment adjustment pattern is less than a thickness of the deposition mask at a remainder of the pattern area, a second deposition area corresponding to lower sub-pixel areas of the mother substrate and including lower deposition openings, a second fixing area corresponding to the lower portion of the mask frame, and a clamping area extended from the second fixing area along the first direction and further than the lower portion of the edge portion of the mask frame.

In an embodiment, the providing of both the first fixing area fixed to the upper portion of the mask frame at the first welded area and the pattern area fixed to the support of the mask frame at the second welded area may align the upper deposition openings in the first deposition area of the deposition mask with the upper sub-pixel areas of the mother substrate. The method may further include for the deposition mask having the lower deposition openings aligned with the lower sub-pixel areas of the mother substrate by the stretching of the clamping area, providing both the pattern area of the deposition mask further fixed to the support of the mask frame at a third welded area, and the second fixing area of the deposition mask fixed to the lower portion of the mask frame at a fourth welded area.

In an embodiment, within the pattern area of the deposition mask, the alignment adjustment pattern may be between the second welded area and the third welded area along the first direction.

According to embodiments, even when the lower openings in the lower deposition area do not accurately overlap the lower sub-pixel areas of the mother substrate, since the mask assembly includes the alignment adjustment pattern, the position of portions of the mask in the pattern area, the lower deposition area and the second fixing area may be adjustable to allow the lower openings to accurately overlap the lower sub-pixel areas. Accordingly, the mask assembly may use a relatively small number of masks, so that a manufacturing cost of the mask assembly may be reduced.

In one or more embodiment of the method of providing or manufacturing the mask assembly, even when the lower openings in the lower deposition area do not accurately overlap the lower sub-pixel areas of the mother substrate, the position of portions of the mask in the pattern area, the lower deposition area and the second fixing area may be adjustable in the alignment adjustment process, so that the lower openings may accurately overlap the lower sub-pixel areas which are under the lower deposition area. Accordingly, the mask assembly may use a relatively small number of masks, so that the cost (or time) of providing the mask assembly may be reduced.

In addition, after the upper openings in the upper deposition area accurately overlap the upper sub-pixel areas of the mother substrate, the position of portions of the mask in the pattern area, the lower deposition area and the second fixing area may be adjustable during the alignment adjustment process, so that the lower openings located in the lower deposition area may accurately overlap the lower sub-pixel areas of the mother substrate which are under the lower deposition area, and thus a precise mask may be manufactured.

Moreover, the mask assembly including the precise mask may allow a deposition material to be accurately deposited at a deposition position, so that defects of pixels in pixel areas (or sub-pixel areas) of the organic light emitting diode display device may be reduced.

### BRIEF DESCRIPTION OF THE DRAWINGS

Embodiments can be understood in more detail from the following description taken in conjunction with the accompanying drawings, in which:

FIG. 1 is a plan view showing an embodiment of a mask assembly;

FIG. 2 is a plan view showing an embodiment of a mask frame included in the mask assembly of FIG. 1;

FIG. 3 is a plan view showing an embodiment of a mask included in the mask assembly of FIG. 1;

FIG. 4 is a plan view showing an embodiment of the mask of FIG. 3;

FIGS. 5 and 6 are perspective views showing an embodiment of the mask frame of FIG. 2;

FIGS. 7 to 21 are plan views showing an embodiment of a method of providing a mask assembly; and

FIGS. 22 to 29 are plan views showing an embodiment of a method of providing a mask assembly.

### DETAILED DESCRIPTION

Hereinafter, embodiments will be described in detail with reference to the accompanying drawings. In the accompanying drawings, same or similar reference numerals refer to the same or similar elements.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

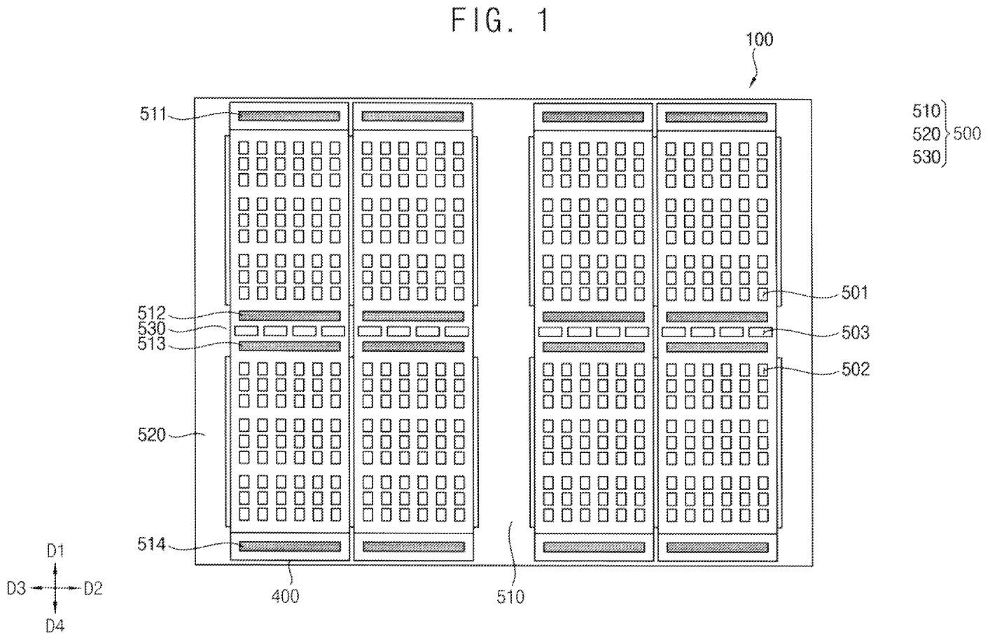

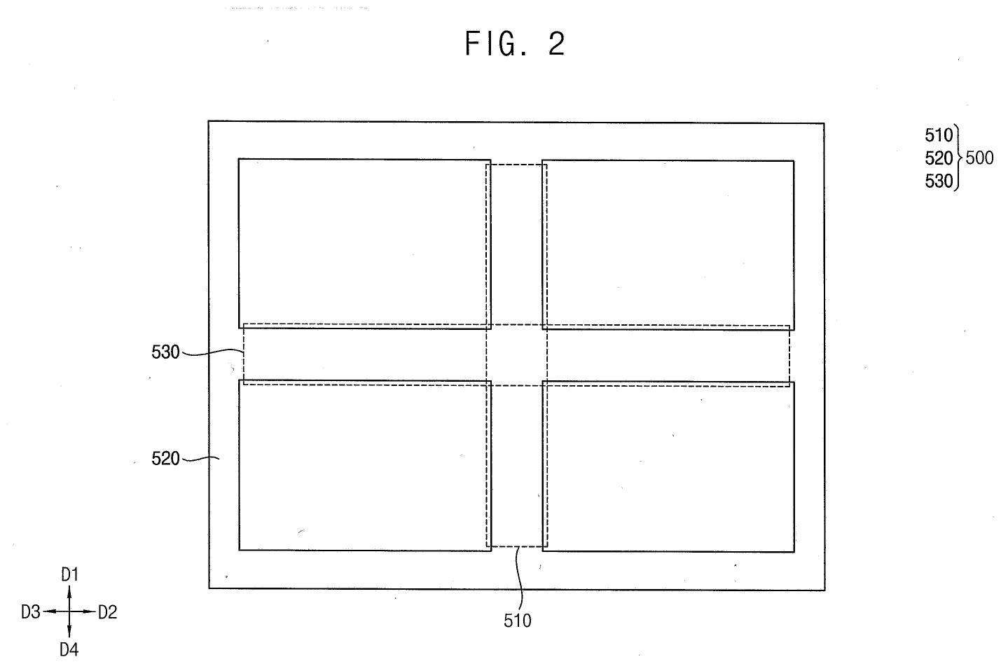

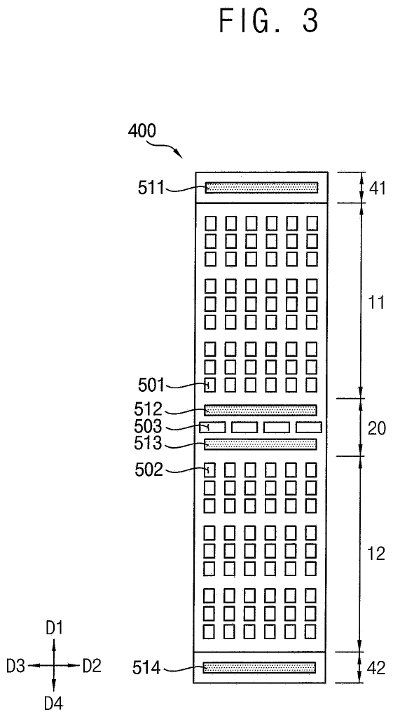

FIG. 1 is a plan view showing an embodiment of a mask assembly 100, and FIG. 2 is a plan view showing an embodiment of a mask frame 500 included in the mask assembly 100 of FIG. 1. FIG. 3 is a plan view showing an embodiment of a mask 400 included in the mask assembly 100 of FIG. 1.

Referring to FIGS. 1, 2 and 3, a mask assembly 100 may include a mask 400 (e.g., deposition mask) provided in plural including masks 400 (e.g., deposition masks), a mask frame 500 and the like. The mask assembly 100 may be disposed in a plane defined by a first direction D1 and a second direction D2 which cross each other. A thickness of the mask assembly 100 and/or components thereof may extend along a thickness direction which crosses the first direction D1 and the second direction D2. The mask 400 as a deposition mask may be disposed extending along the first direction D1 and attachable to the mask frame 500 as a deposition mask frame.

Each of the masks 400 may include a first welding part 512 (e.g., first welded area), a second welding part 513 (e.g., second welded area), a third welding part 511 (e.g., third welded area), a fourth welding part 514 (e.g., fourth welded area), an alignment adjustment pattern 503 provided in plural including alignment adjustment patterns within a group or a row, an upper opening 501 provided in plural including upper openings 501, and a lower opening 502 provided in plural including lower openings 502. The third welding part 511, the first welding part 512, the second welding part 513 and the fourth welding part 514 may be in order along a length of the mask 400, with the first welding part 512 being closer to the first deposition area 11 than the second welding part 513. The upper opening 501 (e.g., upper deposition opening) and the lower opening 502 (e.g., lower deposition opening) may each be a deposition opening which extends through a thickness of the mask 400. The mask 400 may include a solid portion which defines the deposition openings. Solid portions of the mask 400 may alternate with the deposition openings along a deposition area of the mask 400.

The mask frame 500 may include an edge part 520 (e.g., edge portion), a first support part 530 (e.g., first support portion) and a second support part 510 (e.g., second support portion). The first support part 530 and the second support part 510 may be individually or together referred to as a support. The edge part 520 of the mask frame 500 may define an opening therein. In an embodiment, the first welded area may be a planar area at which the deposition mask is attachable to the support (e.g., first support part 530), the second welded area may be a planar area at which the deposition mask is attachable to the support, the third welded area may be a planar area at which the deposition mask is attachable to the upper portion of the deposition mask frame, and the fourth welded area may be a planar area at which the deposition mask is attachable to the lower portion of the deposition mask frame.

In addition, each of the masks 400 may include a pattern area 20, a first deposition area 11 (e.g., upper deposition area), a second deposition area 12 (e.g., lower deposition area), a first fixing area 41 and a second fixing area 42. The first fixing area 41 may be at a first end of the mask 400 and the second fixing area 42 may be at a second end of the mask 400 which is opposite to the first end thereof along a length direction of the mask 400. The pattern area 20 may be a planar area between two deposition areas having deposition openings defined therein. In a plan view, a major dimension of the mask 400 may be extended along the length direction while a minor dimension of the mask 400 may be extended along a width direction thereof.

In the plane in which the mask assembly 100 is disposed (e.g., “on a plane”), the pattern area 20 may be located between the first deposition area 11 and the second deposition area 12, and each of the first deposition area 11, the pattern area 20 and the second deposition area 12 may be located between the first fixing area 41 and the second fixing area 42. In an embodiment, for example, the mask assembly 100 may correspond to a device for depositing an organic light emitting material (e.g., deposition material) on a plurality of cells defined on a mother substrate 700 (e.g., deposition target), and may define a deposition mask assembly.

Each of the masks 400 may extend along the first direction D1 parallel to a top surface of the mask assembly 100, and may be spaced apart from each other along the second direction D2 which crosses the first direction D1. In an embodiment, the second direction D2 may be orthogonal to the first direction D1. The upper openings 501 may be provided or formed in a planar area of the masks 400 which defines the first deposition area 11, and the lower openings 502 may be provided or formed in a planar area of the masks 400 which defines the second deposition area 12. In an embodiment, the organic light emitting material may pass through the mask 400 at the upper openings 501 thereof and the lower openings 502 thereof. That is, the upper deposition openings and the lower deposition openings pass a deposition material therethrough.

The third welding part 511 may be provided or formed in the first fixing area 41 of the mask 400, and the fourth welding part 514 may be provided or formed in the second fixing area 42 of the mask 400. On the plane of the mask assembly 100, the first fixing area 41 may overlap or correspond to a first portion of the edge part 520 (e.g., an upper portion of the edge part 520) of the mask frame 500, and the second fixing area 42 may overlap or correspond to a second portion of the edge part 520 (e.g., a lower portion of the edge part 520) of the mask frame 500. The upper portion and the lower portion may be opposing each other along the first direction D1. The third welding part 511 and the fourth welding part 514 may be a portion of the mask 400 at which the mask 400 is welded to the edge part 520 so as to fix the mask 400 to the edge part 520. The first welding part 512, the second welding part 513 and the alignment adjustment pattern 503 may each be provided or formed in the pattern area 20 of the mask 400.

In an embodiment, on the plane of the mask assembly 100, the alignment adjustment pattern 503 may be located between the first welding part 512 and the second welding part 513. In addition, the pattern area 20 may overlap or correspond to the first support part 530 of the mask frame 500. The first welding part 512 and the second welding part 513 may be an area of the mask 400 which is welded to the first support part 530 so that the mask 400 may be fixed to the first support part 530. Moreover, the alignment adjustment pattern 503 may be provided or formed by removing at least a part of the mask 400 located in the pattern area 20. In an embodiment, the deposition mask (e.g., mask 400) may include a first thickness of the deposition mask at the first welded area, and a second thickness of the deposition mask at the alignment adjustment pattern 503 which is less than the first thickness. In an embodiment, a thickness of the deposition mask at the alignment adjustment pattern 503 may be less than a thickness of the deposition mask at a remainder of the pattern area 20.

Referring to FIGS. 1 and 3, the alignment adjustment pattern 503 may include a plurality of through-openings provided or formed extended through a thickness of the mask 400 located in the pattern area 20, and the through-openings may be spaced apart from each other along the second direction D2. The mask 400 which attached to the mask frame 500 may expose a top surface of the first support part 530 to outside the mask 400 and outside the mask assembly 100 at the through-openings. In other words, the organic light emitting material as a deposition material may not pass from a first side of the mask assembly 100 and through the through-openings of the mask 400 to an opposing second side of the mask assembly 100, since the first support part 530 blocks the deposition material. That is, the support of the deposition mask frame which corresponds to the through-opening of the alignment adjustment pattern 503 blocks passage of a deposition material through the through-opening.

In an embodiment, the alignment adjustment pattern 503 may include a plurality of grooves provided or formed in the mask 400 such as by removing a thickness portion of the mask 400 located in the pattern area 20, and the grooves may be spaced apart from each other along the second direction D2. The groove may be extended into the mask 400 for less than a total thickness of the mask 400, such as to define a thickness portion (e.g., solid portion) of the mask 400 at the pattern area 20 which is less than the total thickness of the mask 400 at a remainder of the pattern area 20.

The mask 400 may include a metallic material. In an embodiment, for example, the mask 400 may be provided or formed including steel use stainless (“SUS”).

In an embodiment of providing the mask assembly 100, the mask 400 may be provided on the mask frame 500, the third welding part 511 may be welded and fixed to the first portion of the edge part 520 of the mask frame 500 and the first welding part 512 may be welded and fixed to the first support part 530 of the mask from 500. After a respective welding portion is fixed to the first support part 530, the alignment adjustment pattern 503 may be provided or formed in the pattern area 20. Then, positions of portions of the mask 400 which respectively correspond to the pattern area 20, the second deposition area 12, and the second fixing area 42 may be adjusted to allow the lower openings 502 at the second deposition area 12 to accurately overlap or correspond to sub-pixel areas 710 of the mother substrate 700 (e.g., target area of a deposition target). In the above processes of providing a mask assembly 100, since the alignment adjustment pattern 503 is provided or formed, a tension degree of freedom for adjusting a position of the mask 400 relative to the mask frame 500 may be guaranteed. In an embodiment, for example, when a position of the mask 400 is adjusted without providing or forming the alignment adjustment pattern 503, the mask 400 may not be moveable or may be broken during position adjustment of portions of the mask 400.

Although the alignment adjustment pattern 503 included in the mask 400 has been shown in the drawings as a plurality of alignment adjustment patterns including four through-openings, the invention is not limited thereto. In an embodiment, for example, the alignment adjustment pattern 503 may include at least two through-openings.

In addition, although each of the through-openings of the alignment adjustment pattern 503 has been shown in the drawings as having a rectangular planar shape when viewed in a plan view, the planar shape of the through-opening is not limited thereto. In an embodiment, for example, each of the through-openings may have a planar shape such as a triangular shape, a rhombic shape, a polygonal shape, a circular shape, a track shape, an elliptical shape or an asymmetrical shape when viewed in a plan view, and the through-openings may have mutually different shapes when viewed in a plan view.

Moreover, although the through-openings of the alignment adjustment pattern 503 have been shown in the drawing as being arranged in one row along the second direction D2, an arrangement of the through-openings is not limited thereto. In an embodiment, for example, the through-openings may be arranged in at least two rows extending along the second direction D2, where the rows are arranged along the first direction D1.

Referring again to FIGS. 1, 2 and 3, along the thickness direction, the mask frame 500 may be disposed under the masks 400. The first support part 530 and the second support part 510 of the mask frame 500 may extend across the opening of the mask frame 500 to reduce or effectively prevent the masks 400 from sagging, and may block the organic light emitting material (e.g., deposition material) from passing through the masks 400 to below the mask assembly 100. In an embodiment, for example, as shown in FIG. 2, the first support part 530 (shown in dotted line box) may extend along the second direction D2 orthogonal to the first direction D1, the second support part 510 (shown in dotted line box) may extend along the first direction D1, and the first support part 530 may intersect the second support part 510. In other words, the first support part 530, the second support part 510 and the edge part 520 may be integral with each other. In addition, the edge part 520 may surround the first support part 530 and the second support part 510 in a top plan view. As described above, the first support part 530 may overlap the pattern area 20 of each of the masks 400, and the first portion and the second portion of the edge part 520 may overlap the first fixing area 41 and the second fixing area 42 of each of the masks 400, respectively. The mask frame 500 may include a metallic material. In an embodiment, for example, the mask frame 500 may include SUS.

Although the mask frame 500 has been described as having one of the first support part 530, the invention is not limited thereto. In an embodiment, for example, a second one of the first support part 530 may be additionally provided between the first portion and the second portion of the edge part 520 without overlapping the upper openings 501 or the lower openings 502.

In addition, although the mask frame 500 has been described as having one of the second support part 510, the invention is not limited thereto. In an embodiment, for example, a second one of the second support part 510 may be additionally provided between a third portion of the edge part 520 (e.g., a left side of the edge part 520) and a fourth portion of the edge part 520 (e.g., a right side of the edge part 520) to cover a space between the masks 400 which are spaced apart from each other along the second direction D2. That is, the masks 400 arranged along the second direction D2 are spaced apart from each other

Accordingly, the mask assembly 100 including the masks 400 and the mask frame 500 may be provided.

In a conventional mask assembly, a plurality of openings through which a deposition material passes may be provided or formed in a conventional mask assembly. The openings may be located to correspond to sub-pixel areas 710 (e.g., areas in which an organic light emitting layer is provided or formed on a deposition target) of an organic light emitting diode display device. As a deposition target such as a mother substrate 700 becomes larger, a deposition mask may be manufactured to have a relatively long length corresponding to a dimension of the mother substrate 700. In a process of providing or forming the openings in the deposition mask, the openings may not be provided or formed in a single process due to the limitation in a size of a processing apparatus which provides the openings in the deposition mask. Where a single process is not possible, some of the openings in one portion such as an upper portion of the deposition mask may be provided and then a remainder of the openings may be provided in another portion such as a lower portion of the deposition mask. However, when some of the openings are provided or formed in the upper portion of the deposition mask and then the remainder of the openings are provided or formed in the lower portion of the deposition mask, the openings in the lower portion of the mask may not accurately overlap or correspond to sub-pixel areas 710 as target deposition areas of the mother substrate 700, so that organic light emitting layers (e.g., deposition pattern) may not be accurately provided or formed in the sub-pixel areas 710, respectively. Because of the above problem, the deposition mask is not manufactured by the above-described method.

Accordingly, in a conventional process of manufacturing a conventional mask assembly, an opening may be provided or formed only in an upper portion of a first mask among a plurality of deposition masks each having an upper portion and a lower portion, the first mask may be welded to a conventional mask frame, and a lower portion of the deposition mask in which the opening is not provided or formed may be removed. Thereafter, an opening may be provided or formed only in a lower portion of a second mask among the plurality of deposition masks which each have the upper portion and the lower portion, the second mask may be welded to the conventional mask frame, and an upper portion of the deposition mask in which the opening is not provided or formed may be removed. Accordingly, a conventional mask may be manufactured.

According to embodiments, even when the lower openings 502 provided or formed in the second deposition area 12 do not accurately overlap or correspond to the sub-pixel areas 710 of the mother substrate 700, since the mask assembly 100 includes the alignment adjustment pattern 503, the positions of portions of the mask 400 respectively at the pattern area 20, the second deposition area 12 and the second fixing area 42 may be adjusted to allow the lower openings 502 to accurately overlap or correspond to the sub-pixel areas 710. Accordingly, the mask assembly 100 may use a relatively small number of masks 400, so that a manufacturing cost of the mask assembly 100 may be reduced.

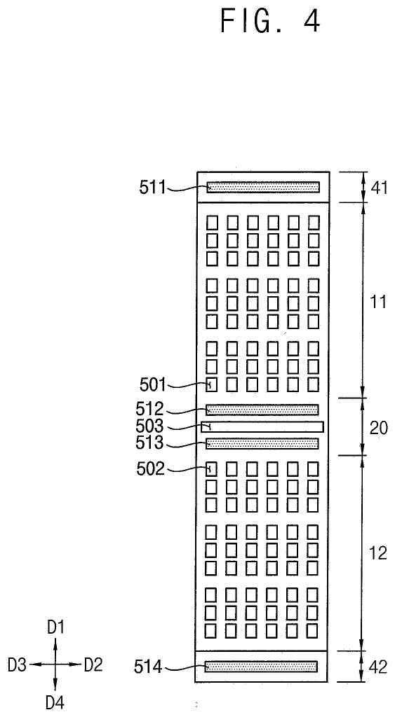

FIG. 4 is a plan view showing an embodiment of the mask 400 of FIG. 1.

Referring to FIG. 4, a single one of the alignment adjustment pattern 503 may be located between the first welding part 512 and the second welding part 513 on the plane of the mask assembly 100. In addition, the pattern area 20 may overlap the first support part 530 of the mask frame 500. The first welding part 512 and the second welding part 513 may be welded to the first support part 530 so that the mask 400 may be fixed to the first support part 530. Moreover, the alignment adjustment pattern 503 may be provided or formed by removing a thickness portion of the mask 400 located in the pattern area 20. In an embodiment, for example, the alignment adjustment pattern 503 may include a through-opening provided or formed through a total thickness of the mask 400 located in the pattern area 20, and a planar shape of the through-opening may extend along the second direction D2. The through-opening of FIG. 4 may have a relatively large dimension along the second direction D2. In other words, the through-opening of FIG. 4 may have a bar shape when viewed in a plan view. The mask 400 which attached to the mask frame 500 may expose the top surface of the first support part 530 to outside the mask 400 and/or the mask assembly 100 at the through-opening. That is, the deposition mask which is attached to the deposition mask frame disposes the top surface of the support exposed to outside the deposition mask by the through-opening of the alignment adjustment pattern 503. In other words, the organic light emitting material may not pass through the through-opening to below the mask assembly 100. In an embodiment, the alignment adjustment pattern 503 may include a groove provided or formed by removing a thickness portion less than a total thickness of the mask 400 located in the pattern area 20, and a planar shape of the groove may extend along the second direction D2.

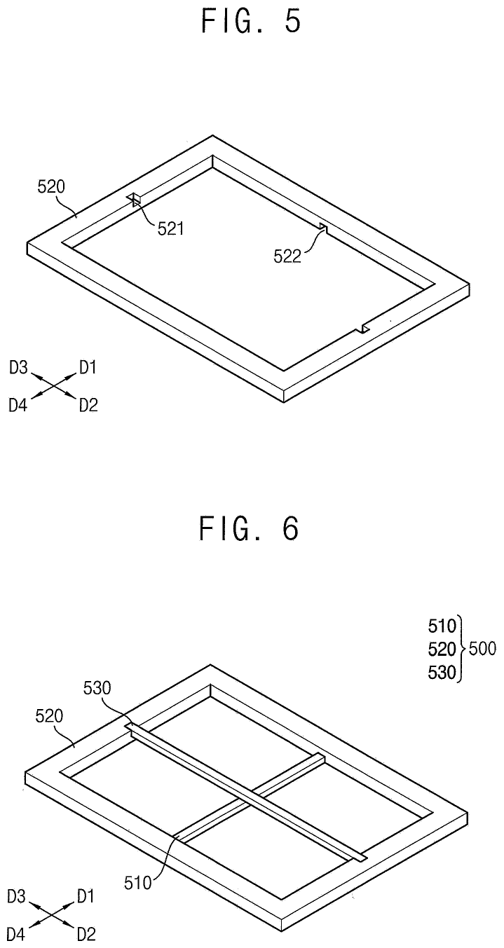

FIGS. 5 and 6 are perspective views showing an embodiment of the mask frame 500 of FIG. 1.

Referring to FIGS. 5 and 6, in the edge part 520, a first groove 521 may be provided in plural including first grooves 521 and a second groove 522 may be provided in plural including second grooves 522. Each of the grooves may be open in a direction towards the opening of defined by the edge part 520. Opposing ends of each of the first support part 530 and the second support part 510 may be engaged with the first and second grooves 521 and 522, respectively. In an embodiment, for example, the opposing ends of the first support part 530 may be coupled to the mask frame 500 at the first grooves 521, and the opposing ends of the second support part 510 may be coupled to the mask frame 500 at the second grooves 522. Referring to FIG. 6, the second support part 510 may be located under the first support part 530 along the third direction D3. The mask frame 500 of FIGS. 5 and 6 may include the first support part 530, the second support part 510 and the edge part 520 as separate pieces which are joined together.

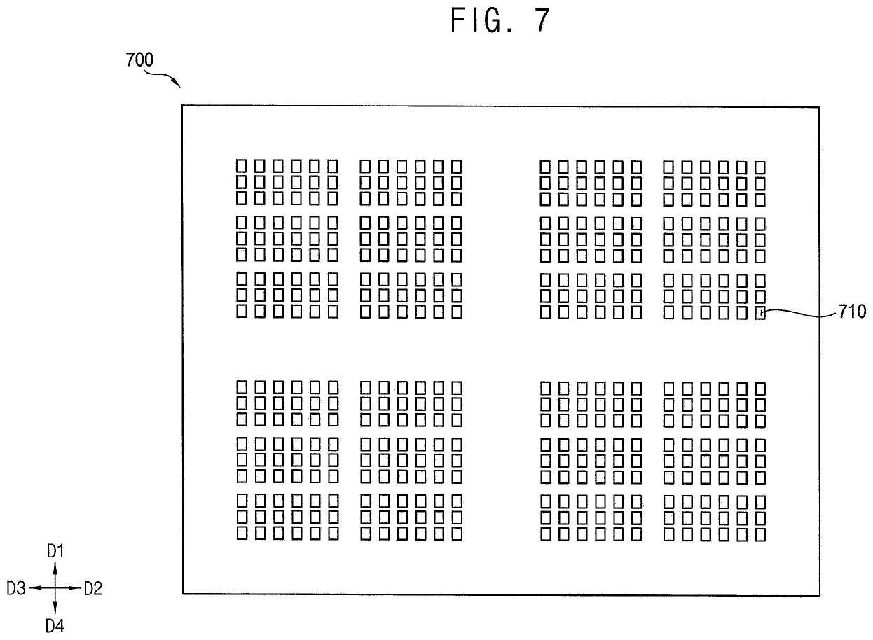

FIGS. 7 to 21 are plan views showing an embodiment of a method of providing a mask assembly 100.

Referring to FIG. 2, the mask frame 500 may be provided. The mask frame 500 may include an edge part 520, a first support part 530 and a second support part 510. The first support part 530 may extend along the second direction D2, the second support part 510 may extend along the first direction D1, and the first support part 530 may intersect the second support part 510. In an embodiment, the first support part 530, the second support part 510 and the edge part 520 may be integrally formed. In addition, the edge part 520 may surround the first support part 530 and the second support part 510. The mask frame 500 may include a metallic material. In an embodiment, for example, the mask frame 500 may include SUS.

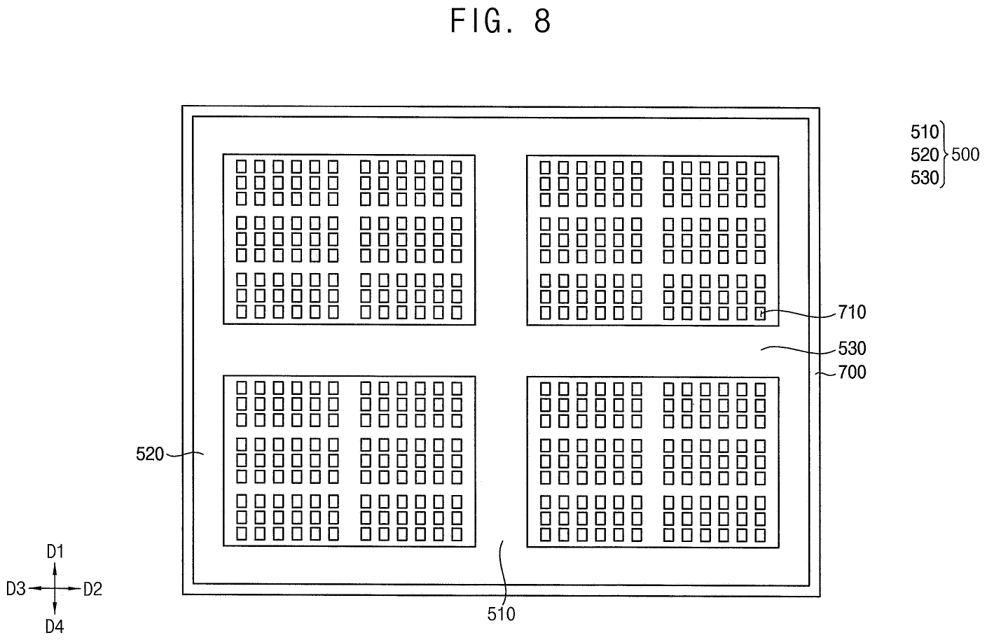

Referring to FIGS. 7 and 8, a mother substrate 700 (e.g., deposition target) may be provided. The mother substrate 700 may include a plurality of cells. In an embodiment, for example, components of a display device may be provided or formed on the mother substrate 700, and a plurality of cells may be separated from each other such as by performing cell cutting. A separated portion of the mother substrate 700 may form a part of the display device without being limited thereto.

Each of the cells may include a sub-pixel area 710 (e.g., target deposition area of the deposition target). The sub-pixel area 710 may be provided in plural including sub-pixel areas 710 including upper sub-pixel areas and lower sub-pixel areas. In an embodiment, when the display device is an organic light emitting diode display device, an organic light emitting layer (e.g., deposition pattern) may be provided or formed in the sub-pixel area 710. In an embodiment, an opening of a pixel defining layer included in the organic light emitting diode display device may correspond to or define the sub-pixel area 710. In addition, one or more embodiment of the mother substrate 700 may have a size relatively larger than a size of a conventional mother substrate. In an embodiment, for example, the mother substrate 700 may extend along the first direction D1 and along the second direction D2 to have a relatively large planar area.

As shown in FIG. 8, the mother substrate 700 may be provided under the mask frame 500. The edge part 520 of the mask frame 500 may overlap outer edge portions of the mother substrate 700. The sub-pixel areas 710 of the mother substrate 700 may be exposed to outside the mask frame 500 through four openings of the mask frame 500 which are defined by the first support part 530 and the second support part 510 together with the edge part 520.

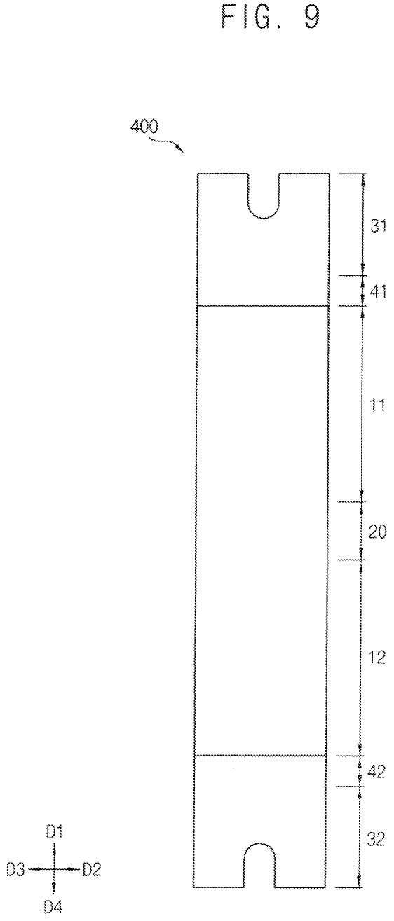

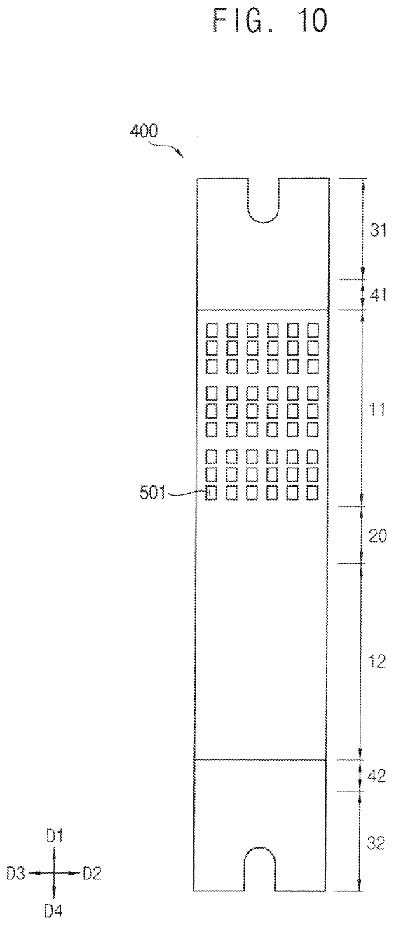

Referring to FIG. 9, the mask 400 in a preliminary form (e.g., preliminary mask) may be provided. The mask 400 may include a pattern area 20, a first deposition area 11, a second deposition area 12, a first fixing area 41, a second fixing area 42, a first clamping area 31 and a second clamping area 32. The first clamping area 31 may be at a first distal end of the mask 400 and the second clamping area 32 may be at a second distal end of the mask 400 which is opposite to the first distal end thereof along a length direction of the mask 400. As the mother substrate 700 becomes larger, the mask 400 may be manufactured to have a relatively long length in the first direction D1 and in a direction opposite to the first direction (e.g., a fourth direction D4). The thickness direction may cross each of the first to fourth directions D1 to D4 described above (e.g., into the view of FIG. 9). The mask 400 may include a metallic material. In an embodiment, for example, the mask 400 may include SUS.

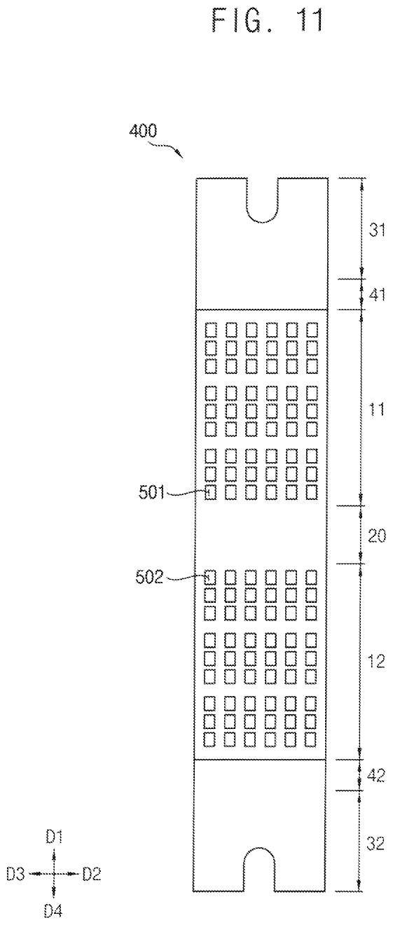

Referring to FIG. 10, the upper openings 501 may be provided or formed in the first deposition area 11 of the mask 400.

In an embodiment, for example, as the length of the mask 400 becomes relatively large, a size of a manufacturing apparatus for providing or forming a deposition opening or a dummy opening in the mask 400 has to be increased. However, even if a new manufacturing apparatus for providing or forming openings in the relatively long mask at a same time or simultaneously is developed, the deposition opening may be provided in only a partial area of the mask 400 by using an existing manufacturing apparatus due to the cost for purchasing the new manufacturing apparatus.

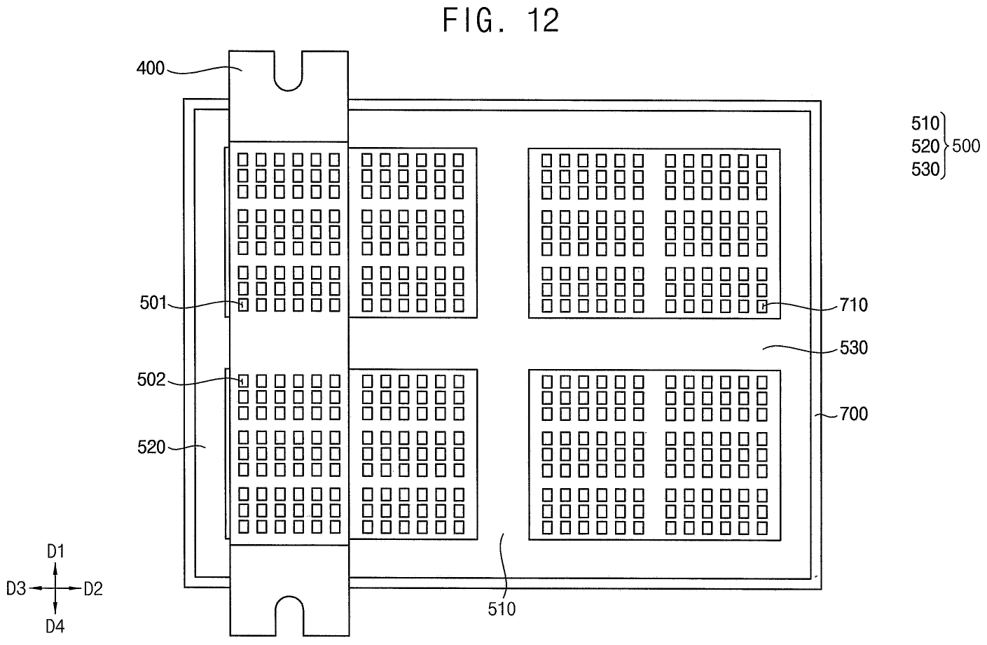

Referring to FIGS. 11 and 12, the upper openings 501 may be provided or formed in the first deposition area 11, and the lower openings 502 may be provided or formed in the second deposition area 12 of the mask 400. After both groups of the deposition opening are provided or formed in the plural deposition areas, the mask 400 in a preliminary form may be placed on the mask frame 500 such that the pattern area 20 of the mask 400 corresponds to or overlaps the first support part 530 of the mask frame 500. In FIG. 12, for example, the method may include providing a deposition mask facing the mother substrate 700 with the mask frame 500 therebetween.′

The mask 400 provided on the mask frame 500 disposes each of the first clamping area 31 and the second clamping area 32 extended further than an outer edge of the mask frame 500 and/or the mother substrate 700. In an embodiment, a clamping area (e.g., second clamping area 32) is extended from the second fixing area 42 along the first direction D1 and further than the lower portion of the edge portion of the mask frame 500.

After the mask 400 in the preliminary form is placed on the mask frame 500, each of the first clamping area 31 and the second clamping area 32 of the mask 400 may be fixed. In an embodiment, for example, a first clamp (not shown) may pull the first clamping area 31 of the mask in the first direction D1 while fixing the first clamping area 31 in a pulled or stretched position, and a second clamp (not shown) may pull the second clamping area 32 in the fourth direction D4 while fixing the second clamping area 32 in a pulled or stretched position. While the first and second clamps pull the mask 400 in the first and fourth directions D1 and D4, the upper openings 501 provided or formed in the first deposition area 11 of the mask 400 may overlap or correspond to the sub-pixel areas 710 of the mother substrate 700 located under the first deposition area 11.

In an embodiment, for example, since the upper openings 501 and the lower openings 502 are not provided or formed at the same time or simultaneously, even when the upper openings 501 provided or formed in the first deposition area 11 accurately correspond to or overlap (e.g., be aligned with) the sub-pixel areas 710 of the mother substrate 700 which is under the first deposition area 11, the lower openings 502 provided or formed in the second deposition area 12 may not accurately correspond to or overlap the sub-pixel areas 710 of the mother substrate 700 which is under the second deposition area 12. In other words, misalignment may occur between the lower openings 502 and the sub-pixel areas 710 of the mother substrate 700 which are under the second deposition area 12. However, the misalignment of the lower openings 502 and the sub-pixel areas 710 may be adjusted through an alignment adjustment process that will be subsequently performed, so that the lower openings 502 may accurately correspond to or overlap the sub-pixel areas 710 of the mother substrate 700 which are under the second deposition area 12.

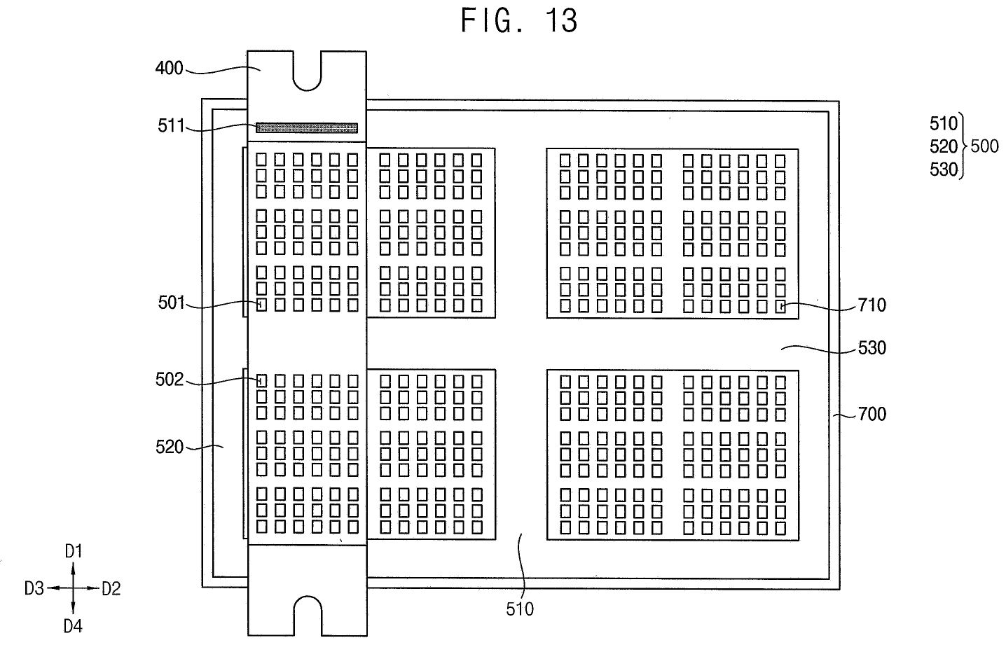

In an embodiment of providing a deposition mask assembly, one of the first clamping area 31 and the second clamping area 32 of the mask 400 may be fixed in position relative to the mask frame 500. Referring to FIG. 13, the first fixing area 41 of the mask 400 may overlap the first portion of the edge part 520 (e.g., the upper portion of the edge part 520) of the mask frame 500. The third welding part 511 may be provided or formed by welding a portion of the first fixing area 41 of the mask 400 to the edge portion such as by using a continuous wave (“CW”) laser. In an embodiment, for example, the third welding part 511 may extend in the second direction D2 and in a direction opposite to the second direction (e.g., a third direction D3). In other words, the third welding part 511 may be fixed to the first portion of the edge part 520 so that a position of the first fixing area 41 may be fixed relative to the first portion of the edge part 520. The mask 400 which is fixed to the mask frame 500 at the first fixing area 41 disposes remaining portions of the mask 400 (e.g., the pattern area 20, the first deposition area 11, the second deposition area 12, the first fixing area 41, the second fixing area 42 and the second clamping area 32) moveable in position relative to the mask frame 500 and/or the mother substrate 700. That is, the mask 400 which is fixed to the mask frame 500 at the first fixing area 41 disposes a remaining portion of the mask 400 including at least the second deposition area 12 and the lower openings 502 moveable in position relative to the mask frame 500 and/or the mother substrate 700.

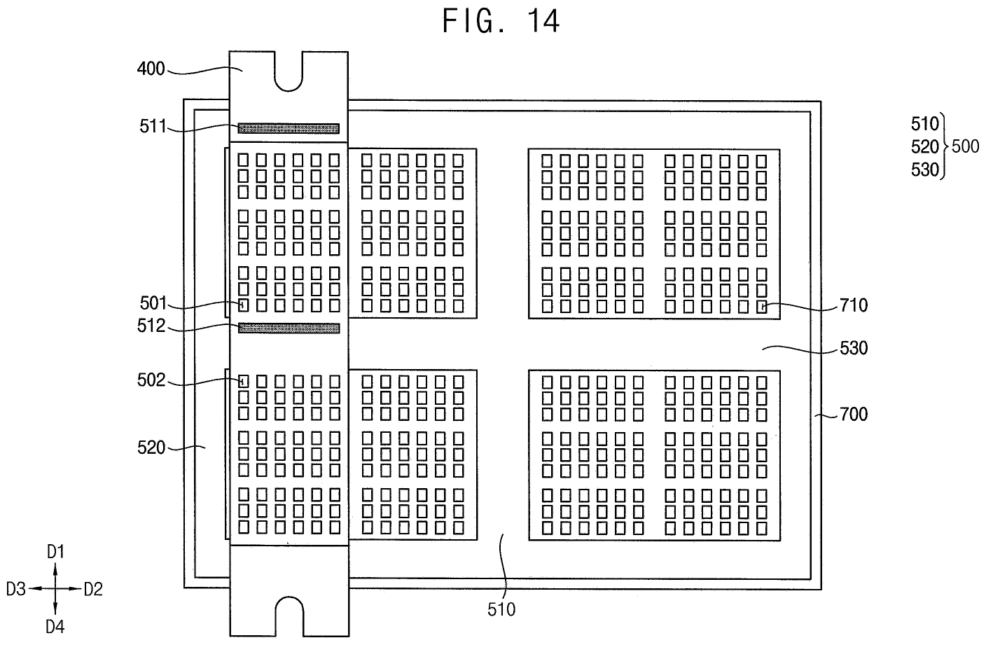

Referring to FIG. 14, the pattern area 20 may overlap the first support part 530 of the mask frame 500. After the third welding part 511 is formed, the first welding part 512 may be provided or formed by welding a first portion of the pattern area 20 of the mask 400 such as by using the CW laser. In an embodiment, for example, the first welding part 512 may extend along the second direction D2. In other words, the first welding part 512 may be welded to a first portion of the first support part 530 so that the first portion of the pattern area 20 may be fixed to the first portion of the first support part 530. The mask 400 which is fixed to the mask frame 500 at the first portion of the pattern area 20 disposes a remaining portion of the mask 400 including at least the second deposition area 12 and the lower openings 502 moveable in position relative to the mask frame 500 and/or the mother substrate 700. In an embodiment, the providing of both the first fixing area 41 fixed to the upper portion of the mask frame 500 at the first welded area and the pattern area 20 fixed to the support (e.g., first support part 530) of the mask frame 500 at the second welded area aligns the upper deposition openings (e.g., upper openings 501) in the first deposition area 11 of the deposition mask with the upper sub-pixel areas of the mother substrate 700 (e.g., sub-pixel areas 710 corresponding to the first deposition area 11).

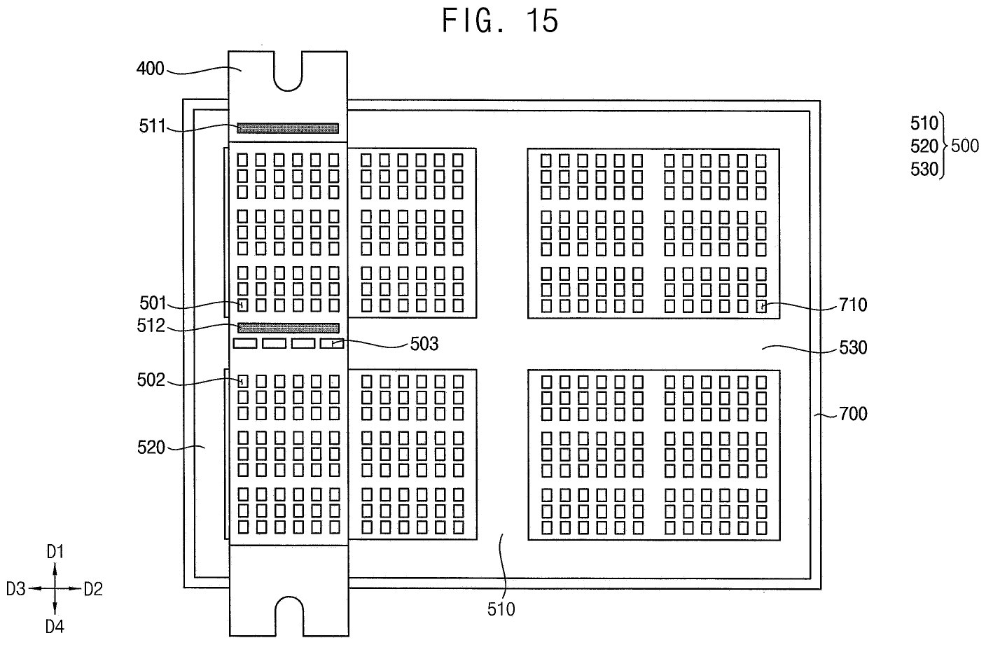

Referring to FIG. 15, after the first welding part 512 is provided or formed, the alignment adjustment pattern 503 may be provided or formed in a second portion of the pattern area 20 (e.g., a portion spaced apart from the first portion of the pattern area 20 in the fourth direction D4) such as by using a pulse laser. The alignment adjustment pattern 503 may be provided or formed by removing a thickness portion of the mask 400 located in the pattern area 20. In an embodiment, for example, the alignment adjustment pattern 503 may include a plurality of through-openings provided or formed extended completely through a thickness of the mask 400 located in the pattern area 20, and the through-openings may be spaced apart from each other along the second direction D2. The mask 400 which is fixed to the mask frame 500 at the second portion of the pattern area 20 and includes the alignment adjustment pattern 503 as a through-opening disposes a top surface of a second portion of the first support part 530 exposed to outside the mask 400 at the through-opening.

In an embodiment, the alignment adjustment pattern 503 may include a plurality of grooves provided or formed by removing a thickness portion of the mask 400 located in the pattern area 20 which is less than a total thickness therein, and the grooves may be spaced apart from each other along the second direction D2. The mask 400 which is fixed to the mask frame 500 at the second portion of the pattern area 20 and includes the alignment adjustment pattern 503 as a groove disposes a top surface of a second portion of the first support part 530 not exposed to outside the mask 400 at the groove since a solid portion of the mask 400 remains at the groove.

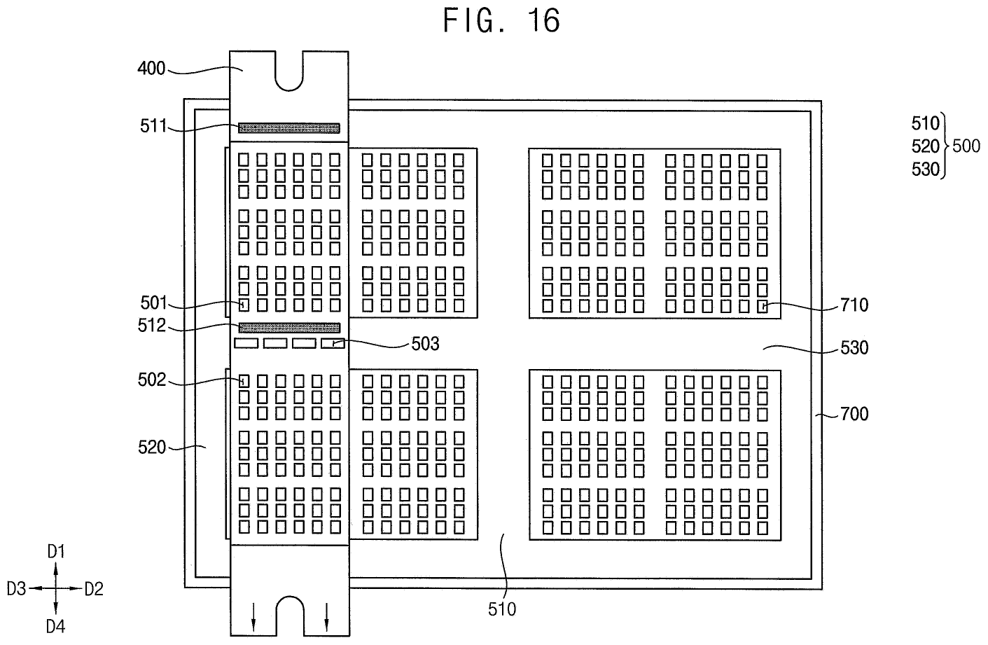

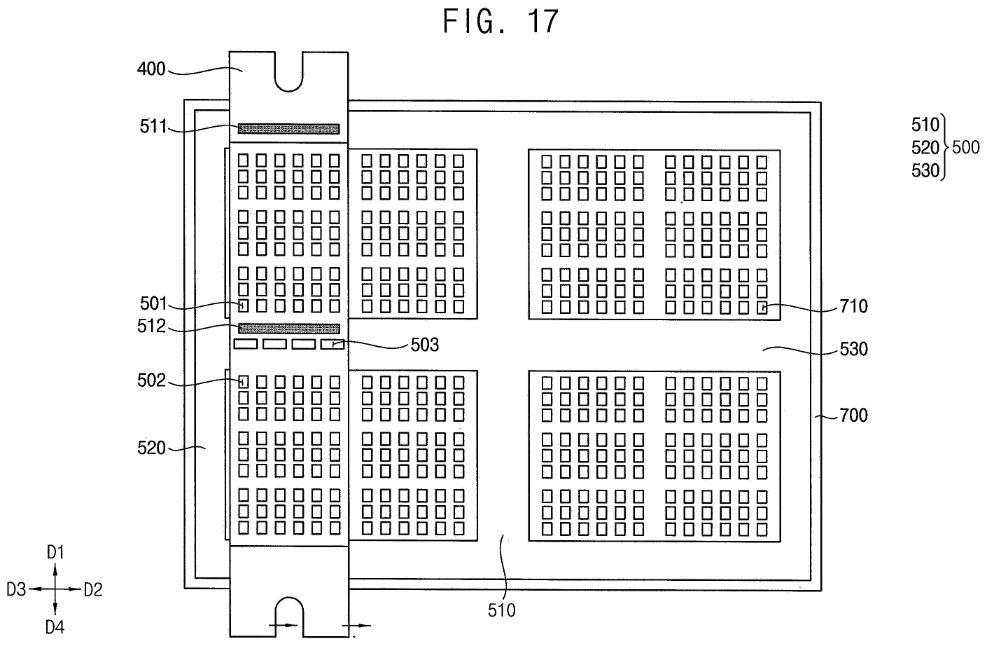

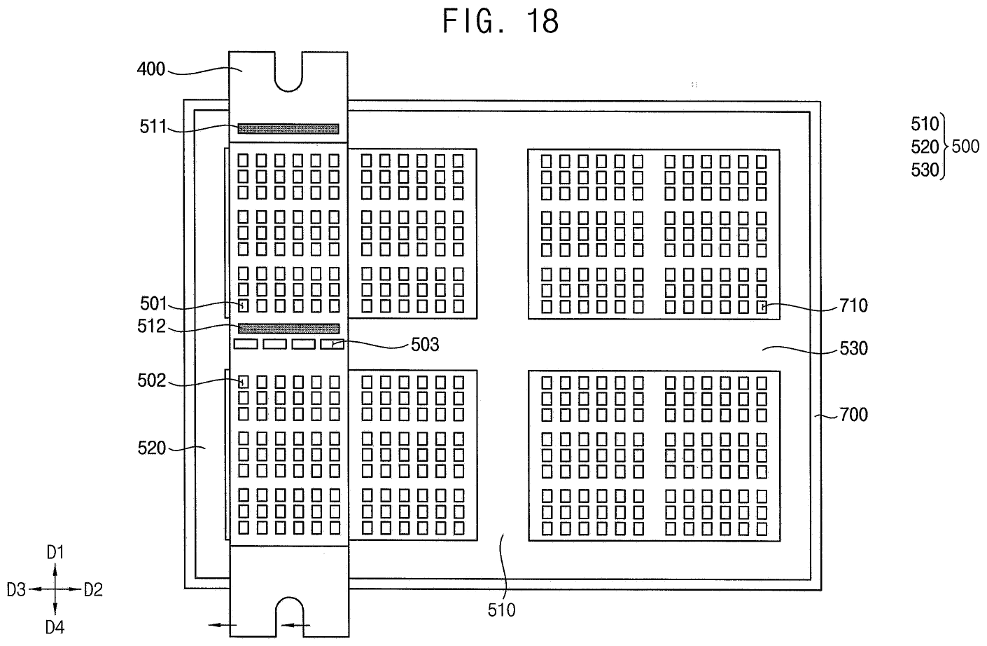

Referring to FIGS. 16, 17, and 18, the second clamping area 32 which is previously stretched and fixed, may be further stretched in the fourth direction D4 (downward arrows in FIG. 16), the second direction D2 (rightward arrows in FIG. 17) and/or the third direction D3 (leftward arrows in FIG. 18) (e.g., directions different from the first direction D1). In an embodiment, for the deposition mask which has the alignment adjustment pattern 503 and is fixed to the mask frame 500 at the first welded area and the second welded area, the method may include providing stretching of the clamping area (e.g., second clamping area 32) in a direction different from the first direction D1, to align the lower deposition openings (e.g., lower openings 502) with the lower sub-pixel areas (e.g., sub-pixel areas 710 corresponding to the second deposition area 12).

The stretching of the second clamping area 32 in a direction different from the first direction D1 adjusts the position of a third portion of the pattern area 20, the second deposition area 12 and/or the second fixing area 42 to locate the lower openings 502 provided or formed in the second deposition area 12 to correspond to or overlap the sub-pixel areas 710 of the mother substrate 700 which are under the second deposition area 12. In the above process, since the alignment adjustment pattern 503 having a reduced thickness is provided or formed, the tension degree of freedom for adjusting the position of the mask 400 may be increased. In an embodiment, for example, when the position of a conventional mask excludes the alignment adjustment pattern 503, the conventional mask may not be moveable or may be broken.

In an embodiment, the upper openings 501 provided or formed in the first deposition area 11 and the sub-pixel areas 710 of the mother substrate 700 which are under the first deposition area 11 may correspond to or overlap each other by fixing of the mask 400 at the third welding part 511 and the first welding part 512. Even when the lower openings 502 provided or formed in the second deposition area 12 do not correspond to or overlap the sub-pixel areas 710 of the mother substrate 700 which are under the second deposition area 12, the position of the mask 400 may be adjusted by pulling on the second clamping area 32 in a direction different from the first direction D1 to allow the lower openings 502 provided or formed in the second deposition area 12 to accurately overlap the sub-pixel areas 710 of the mother substrate 700 which are under the second deposition area 12. The above process is defined as the alignment adjustment process. Original shapes of the alignment adjustment pattern 503 may be deformed by the alignment adjustment process.

Movement of the mask 400 by applying a force in the first direction D1 may be difficult. In one or more embodiment, the mask 400 is moveable relative to the mask frame 500 by applying a force to the second clamping area 32 in the direction different from the first direction D1. In an embodiment, the mask 400 may be moveable by applying a force to the second clamping area 32 in the first direction D1 to deform the shapes of the through-openings depending on a material or characteristics of the mask 400. Here, a force may be applied to the second clamping area 32 in all directions to allow the lower openings 502 provided or formed in the second deposition area 12 to correspond to or overlap the sub-pixel areas 710 of the mother substrate 700 which are under the second deposition area 12.

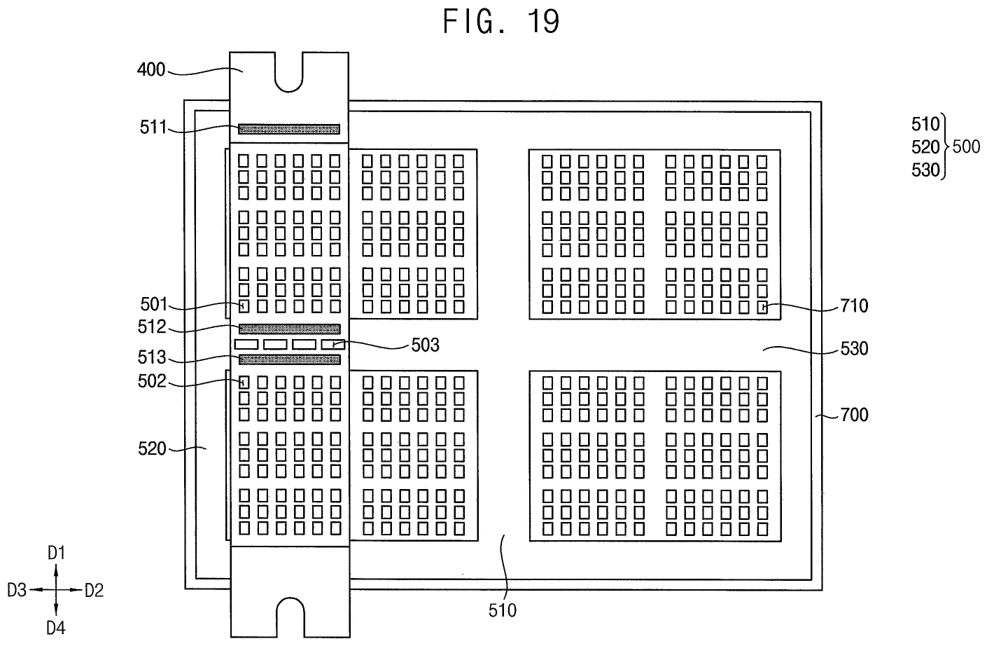

Referring to FIG. 19, after the alignment adjustment pattern 503 is provided or formed and the alignment adjustment process is completed, the second welding part 513 may be provided or formed by welding a third portion of the pattern area 20 (e.g., a portion spaced apart from the alignment adjustment pattern 503 in the fourth direction D4) of the mask 400 such as by using the CW laser. In an embodiment, for example, the second welding part 513 may extend along the second direction D2. The second welding part 513 may be welded to a third portion of the first support part 530 so that the third portion of the pattern area 20 may be fixed to the third portion of the first support part 530. The mask 400 which is fixed to the mask frame 500 at the second welding part 513 disposes a remaining portion of the mask 400 including at least the second deposition area 12 and the lower openings 502 moveable in position relative to the mask frame 500 and/or the mother substrate 700. In an embodiment, the deposition mask (e.g., mask 400) which is attached to the deposition mask frame (e.g., mask frame 500) may be attached to the support (e.g., first support part 530) at both the first welded area and the second welded area (e.g., the first welding part 512 and the second welding part 513) and may be unattached from the support at the alignment adjustment pattern 503.

In an embodiment, for example, the second portion of the pattern area 20 may be located between the first portion and the third portion of the pattern area 20, and the second portion of the first support part 530 may be located between the first portion and the third portion of the first support part 530. In other words, the alignment adjustment pattern 503 may be located between the first welding part 512 and the second welding part 513.

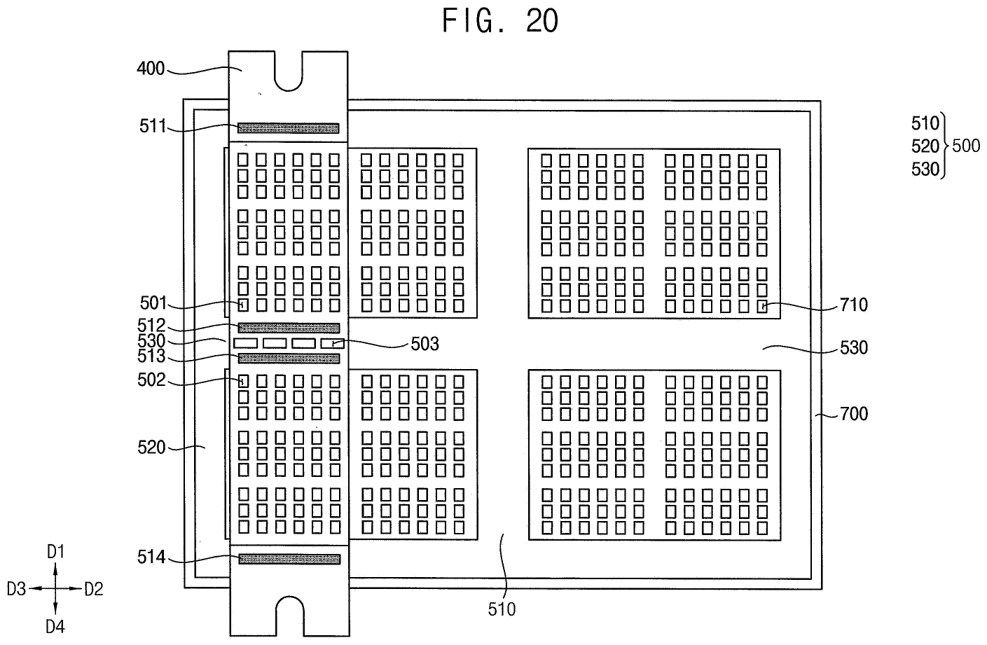

Referring to FIG. 20, the second fixing area 42 of the mask 400 may overlap the second portion of the edge part 520 (e.g., the lower portion of the edge part 520) of the mask frame 500. After the second welding part 513 is provided or formed, the fourth welding part 514 may be provided or formed by welding a part of the second fixing area 42 of the mask 400 such as by using the CW laser. In an embodiment, for example, the fourth welding part 514 may extend along the second direction D2. The fourth welding part 514 may be welded to the second portion of the edge part 520 so that the second fixing area 42 may be fixed to the second portion of the edge part 520. The mask 400 which is fixed to the mask frame 500 at the fourth welding part 514 disposes the second deposition area 12 and the lower openings 502 non-moveable in position relative to the mask frame 500 and/or the mother substrate 700.

In an embodiment, the method may further include for the deposition mask having the lower deposition openings aligned with the lower sub-pixel areas of the mother substrate 700 by the stretching of the clamping area, providing both the pattern area 20 of the deposition mask further fixed to the support of the mask frame 500 at a third welded area, and the second fixing area 42 of the deposition mask fixed to the lower portion of the mask frame 500 at a fourth welded area. That is, the deposition mask which is attached to the deposition mask frame at the third welded area and the first welded area fixes a position of the upper deposition openings in the first deposition area 11 relative to the deposition mask frame, and the deposition mask which is attached to the deposition mask frame at the second welded area and the fourth welded area fixes a position of the lower deposition openings in the second deposition area 12 relative to the deposition mask frame.

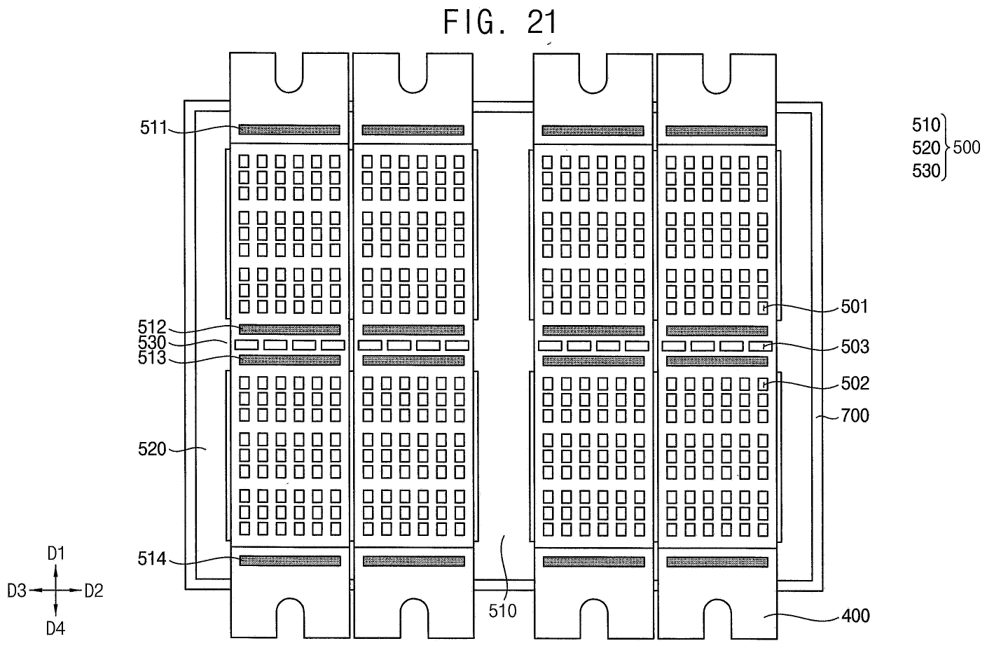

Referring to FIG. 21, a plurality of masks 400 may be provided on the mask frame 500 in the above-described manner. In an embodiment, the alignment adjustment process for each of the masks 400 may include first positioning the upper openings 501 provided or formed in the first deposition area 11 of each of the masks 400 to correspond to or overlap the sub-pixel areas 710 of the mother substrate 700 which are under the first deposition area 11, and second positioning of the lower openings 502 provided or formed in the second deposition area 12 of the mask 400 which has the upper openings 501 corresponding to the sub-pixel areas 710 which are under the first deposition area 11, to correspond to or overlap the sub-pixel areas 710 of the mother substrate 700 which are under the second deposition area 12.

Referring to FIGS. 13 to 20, fixing of the mask 400 at a respective welding part reduces a planar area of the mask 400 which is moveable relative to the mask frame 500. FIG. 13 may show a maximum area of the mask 400 which is moveable relative to the mask frame 500, while FIG. 20 may show a minimum area of the mask 400 which is moveable relative to the mask frame 500. A solid portion of the mask 400 which is between adjacent deposition areas (e.g., pattern area 20) may have a relatively large thickness inhibiting movability of the mask 400. However, in one or more embodiment, a thickness of the solid portion which is between adjacent deposition areas is decreased to increase movability of the mask 400 at the planar area which is between the adjacent deposition areas.

Referring to FIG. 1, after the masks 400 are provided on the mask frame 500, the first and second clamps may be separated from the first clamping area 31 and the second clamping area 32, respectively, and the first clamping area 31 and the second clamping area 32 may be removed from a remainder of the masks 400 such as through a mask cutting process. Accordingly, the mask assembly 100 shown in FIG. 1 may be provided. After the mask assembly 100 is provided, a deposition material (e.g., an organic light emitting material) may pass through the upper openings 501 and the lower openings 502 of the mask 400 so that the deposition material may be deposited on each of the sub-pixel areas 710 of the mother substrate 700.

In the method of providing the mask assembly 100, even when the lower openings 502 provided in the second deposition area 12 do not accurately overlap the sub-pixel areas 710 of the mother substrate 700 owing to the process of providing all of the openings in the mask 400 at different times, in different processes, etc., the position of the pattern area 20, the second deposition area 12 and the second fixing area 42 of the mask 400 may be adjusted through the alignment adjustment process, so that the lower openings 502 may accurately overlap the sub-pixel areas 710 which are under the second deposition area 12. Accordingly, the mask assembly 100 may use a relatively small number of masks 400, so that the manufacturing cost of the mask assembly 100 may be reduced.

In addition, after the upper openings 501 located in the first deposition area 11 accurately overlap the sub-pixel areas 710 of the mother substrate 700 and the position of the first deposition area 11 is fixed relative to the mask frame 500, the position of the pattern area 20, the second deposition area 12 and the second fixing area 42 of the mask 400 having the first deposition area 11 fixed may be adjusted through the alignment adjustment process, so that the lower openings 502 located in the second deposition area 12 may accurately overlap the sub-pixel areas 710 of the mother substrate 700 which are under the second deposition area 12. Thus, a precise form of the mask 400 may be provided.

Moreover, the mask assembly 100 including the mask 400 which is precise may allow a deposition material to be accurately deposited at a deposition position (e.g., target area) to provide a deposition pattern, so that defects of pixels of the organic light emitting diode display device which include the deposition pattern may be reduced.

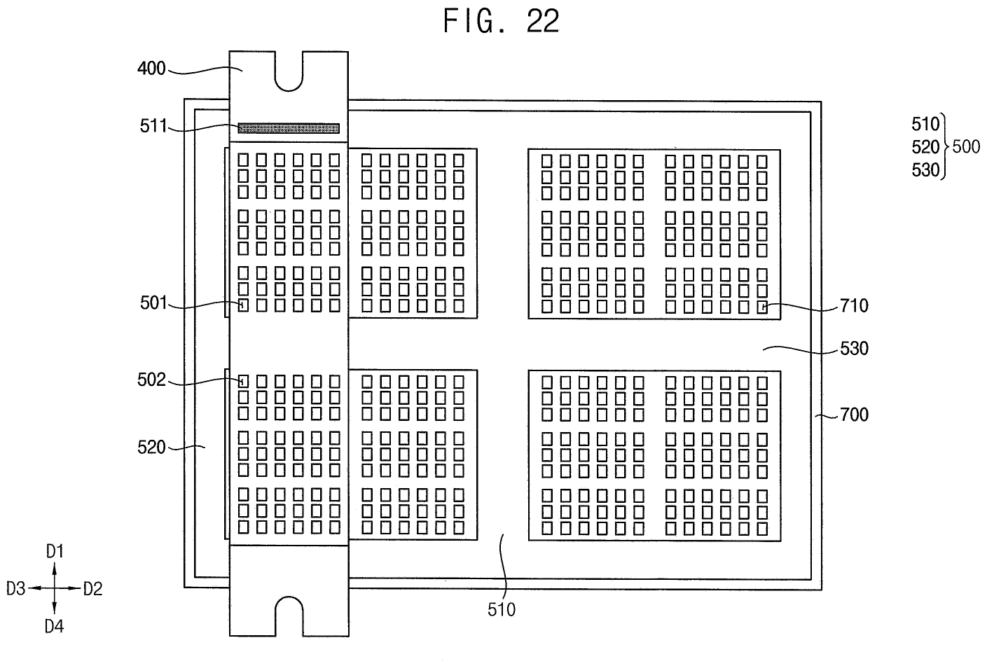

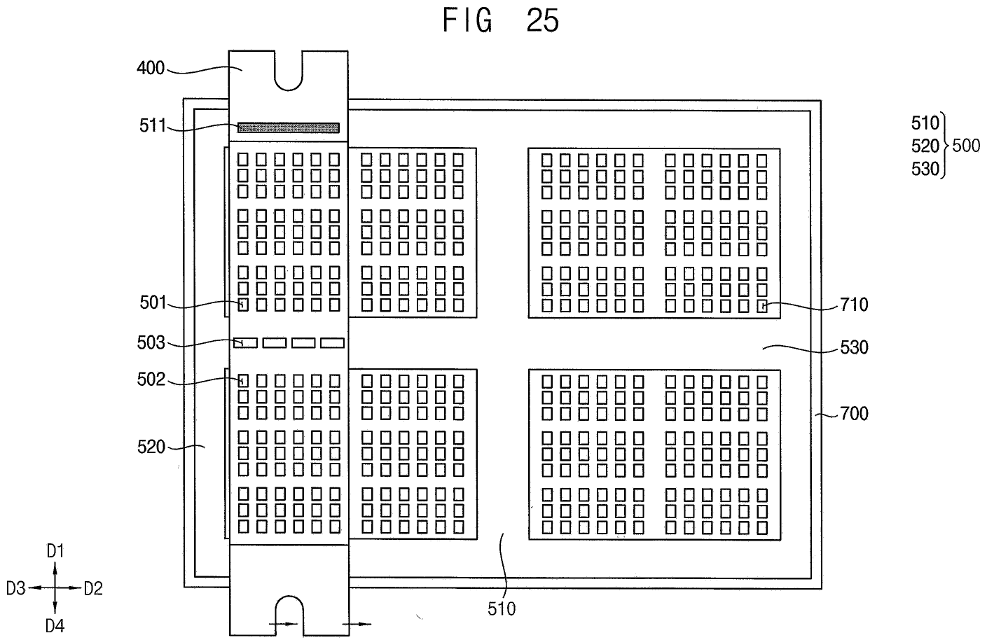

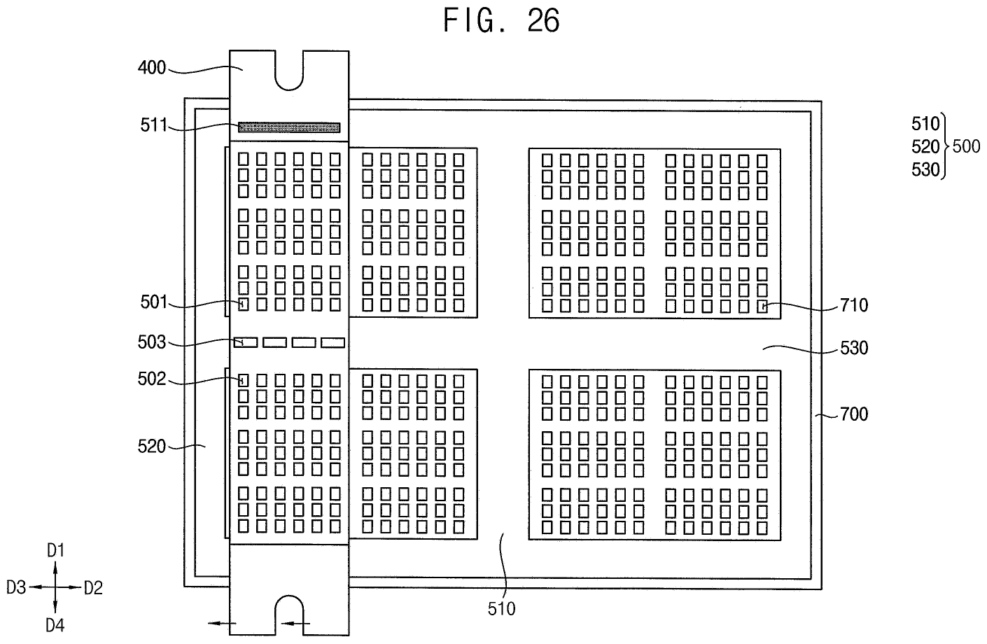

FIGS. 22 to 29 are plan views showing an embodiment of a method of providing a mask assembly 100. A deposition method using a mask assembly 100 illustrated in FIGS. 22 to 29 may be substantially identical or similar to the deposition method using the mask assembly 100 described with reference to FIGS. 7 to 21. In FIGS. 22 to 29, redundant descriptions of components that are substantially identical or similar to the components described with reference to FIGS. 7 to 21 will be omitted.

Referring to FIG. 22, the upper openings 501 provided or formed in the first deposition area 11 of the mask 400 may correspond to or overlap the sub-pixel areas 710 of the mother substrate 700 which are under the first deposition area 11.

The first fixing area 41 of the mask 400 may overlap the first portion of the edge part 520 (e.g., the upper portion of the edge part 520) of the mask frame 500. After the upper openings 501 are positioned to correspond to or overlap the sub-pixel areas 710 of the mother substrate 700 which are under the first deposition area 11, the third welding part 511 may be formed by welding a part of the first fixing area 41 of the mask 400 such as by using the CW laser. In an embodiment, for example, the third welding part 511 may extend in the second direction D2 (or the third direction D3). In other words, the third welding part 511 may be welded to the first portion of the edge part 520 so that the first fixing area 41 may be fixed to the first portion of the edge part 520.

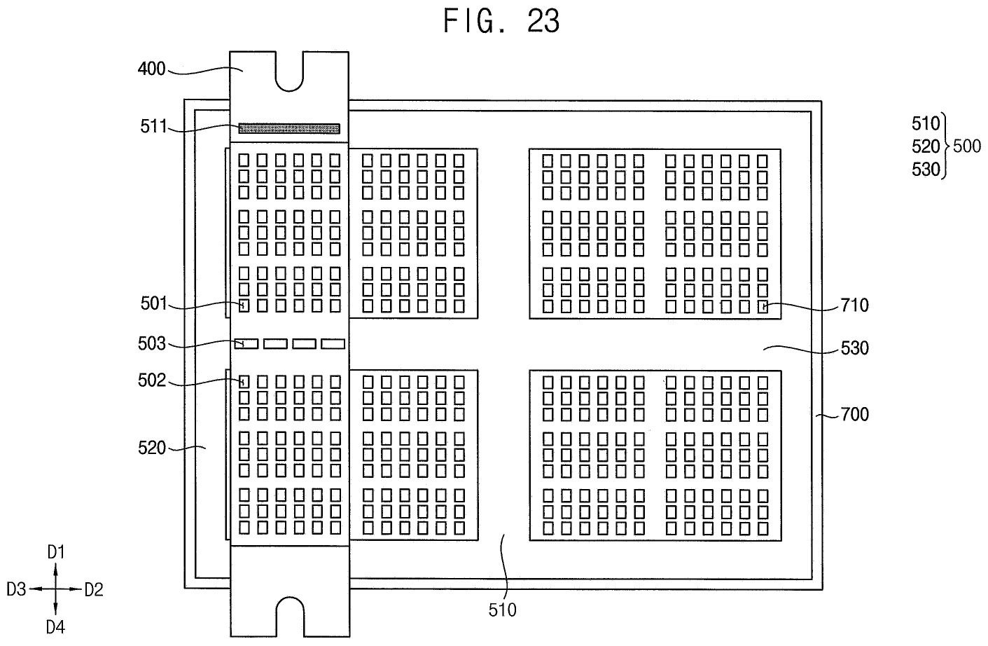

Referring to FIG. 23, the pattern area 20 may overlap the first support part 530 of the mask frame 500. After the third welding part 511 is provided or formed, the alignment adjustment pattern 503 may be provided or formed in a first portion of the pattern area 20 such as by using the pulse laser. The alignment adjustment pattern 503 may be provide or formed by removing a thickness portion of the mask 400 located in the pattern area 20. In an embodiment, for example, the alignment adjustment pattern 503 may include a plurality of through-openings extended completely through a thickness of the mask 400 located in the pattern area 20, and the through-openings may be spaced apart from each other along the second direction D2. The mask 400 which is fixed to the mask frame 500 at the first fixing area 41 and includes the alignment adjustment pattern 503 as a through-opening disposes a top surface of a first portion of the first support part 530 exposed to outside the mask 400 at through the through-openings.

In an embodiment, the alignment adjustment pattern 503 may include a plurality of grooves provided or formed by removing a thickness portion of the mask 400 located in the pattern area 20 which is less than a total thickness of the mask 400, and the grooves may be spaced apart from each other along the second direction D2.

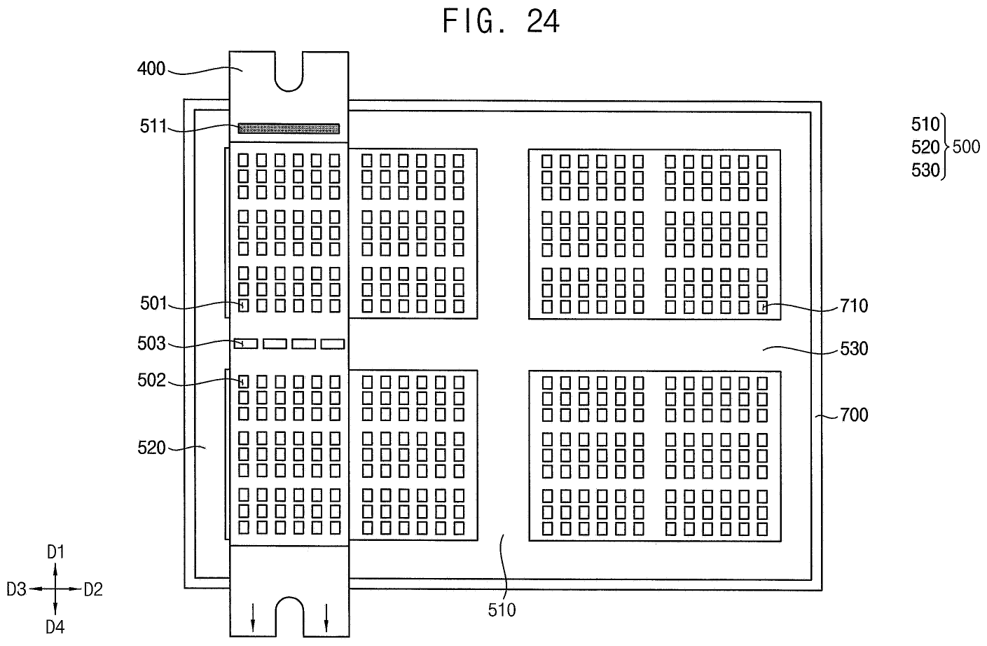

Referring to FIGS. 24, 25 and 26, the mask 400 which is fixed to the mask frame 500 at only the first fixing area 41 may be stretched by movement of the second clamping area 32 in the fourth direction D4, the second direction D2 and/or the third direction D3 (e.g., the directions different from the first direction D1). The position of the pattern area 20, the second deposition area 12 and the second fixing area 42 of the mask 400 which is fixed to the mask frame 500 at only the first fixing area 41 may be adjusted to allow the lower openings 502 provided or formed in the second deposition area 12 to correspond to or overlap the sub-pixel areas 710 of the mother substrate 700 which are under the second deposition area 12. In the above process, since the alignment adjustment pattern 503 is provided or formed in the solid portion of the mask 400 at the pattern area 20, the tension degree of freedom for adjusting the position of the mask 400 may be increased. In an embodiment, for example, when the position of a conventional mask is adjusted without providing the alignment adjustment pattern 503, the conventional mask may not be moveable or may be broken.

The mask 400 including the upper openings 501 provided in the first deposition area 11 and positioned to correspond to the sub-pixel areas 710 of the mother substrate 700 which are under the first deposition area 11, may be stretched in the direction different from the first direction D1 to allow the lower openings 502 provided in the second deposition area 12 to accurately correspond to or be aligned with the sub-pixel areas 710 of the mother substrate 700 which are located under the second deposition area 12. The above process is defined as an alignment adjustment process. The original shapes of the alignment adjustment pattern 503 may be deformed through the alignment adjustment process.

Movement of the mask 400 by applying a force in the first direction D1 may be difficult. In one or more embodiment, the mask 400 is stretched by applying a force to the second clamping area 32 in the direction different from the first direction D1. In an embodiment, if the mask 400 may be moveable by applying a force to the second clamping area 32 in the first direction D1 to deform the shapes of the through-openings depending on a material or characteristics of the mask 400. Here, a force may be applied to the second clamping area 32 in all directions to allow the lower openings 502 provided or formed in the second deposition area 12 to correspond to overlap the sub-pixel areas 710 of the mother substrate 700 which are under the second deposition area 12.

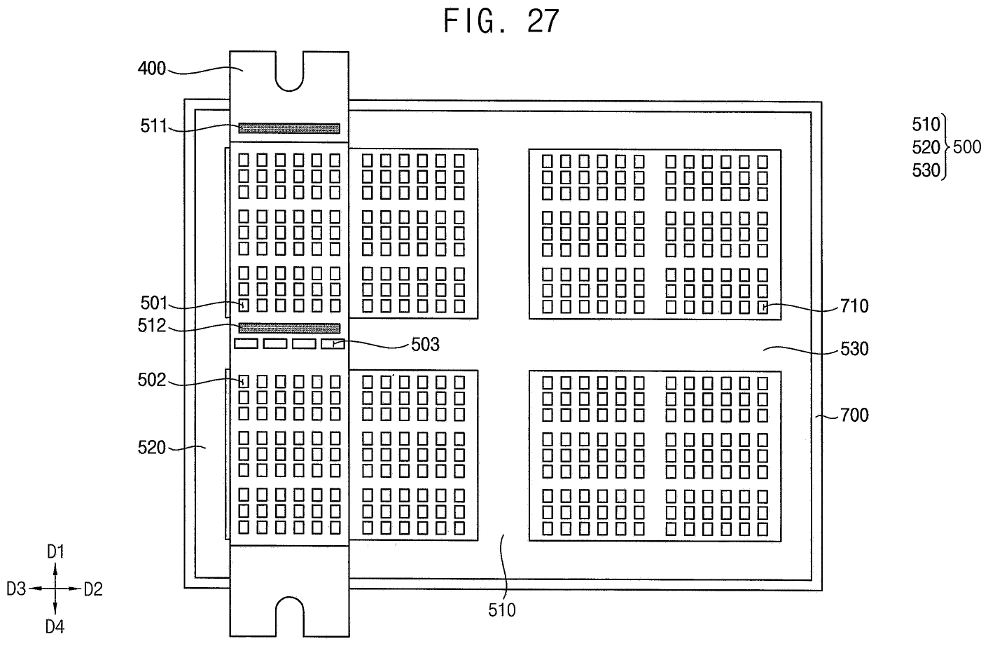

Referring to FIG. 27, after the alignment adjustment pattern 503 is provided or formed, the first welding part 512 may be provided or formed by welding a second portion of the pattern area 20 (e.g., a portion spaced apart from the first portion of the pattern area 20 in the first direction D1) of the mask 400 such as by using the CW laser. In an embodiment, for example, the first welding part 512 may extend along the second direction D2. In an embodiment, the first welding part 512 may be welded to a second portion of the first support part 530 so that the second portion of the pattern area 20 may be fixed to the second portion of the first support part 530.

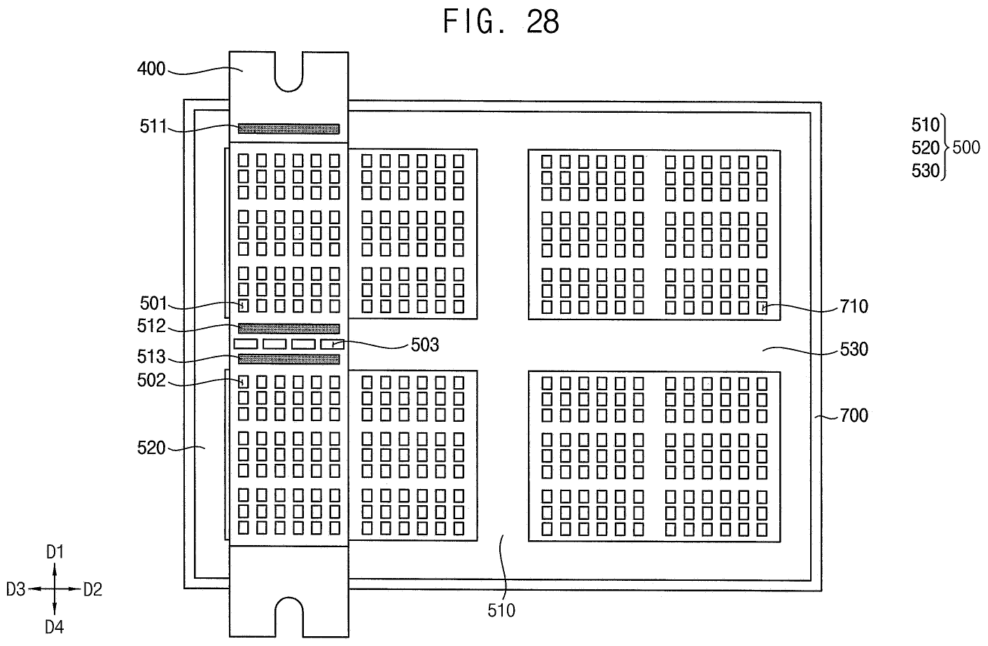

Referring to FIG. 28, after the first welding part 512 is provided or formed, the second welding part 513 may be provided or formed by welding a third portion of the pattern area 20 (e.g., a portion spaced apart from the alignment adjustment pattern 503 in the fourth direction D4) of the mask 400 such as by using the CW laser. In an embodiment, for example, the second welding part 513 may extend along the second direction D2. In an embodiment, the second welding part 513 may be welded to a third portion of the first support part 530 so that the third portion of the pattern area 20 may be fixed to the third portion of the first support part 530. In an embodiment, for example, the first portion of the pattern area 20 may be located between the second portion and the third portion of the pattern area 20, and the first portion of the first support part 530 may be located between the second portion and the third portion of the first support part 530. In other words, the alignment adjustment pattern 503 may be located between the first welding part 512 and the second welding part 513.

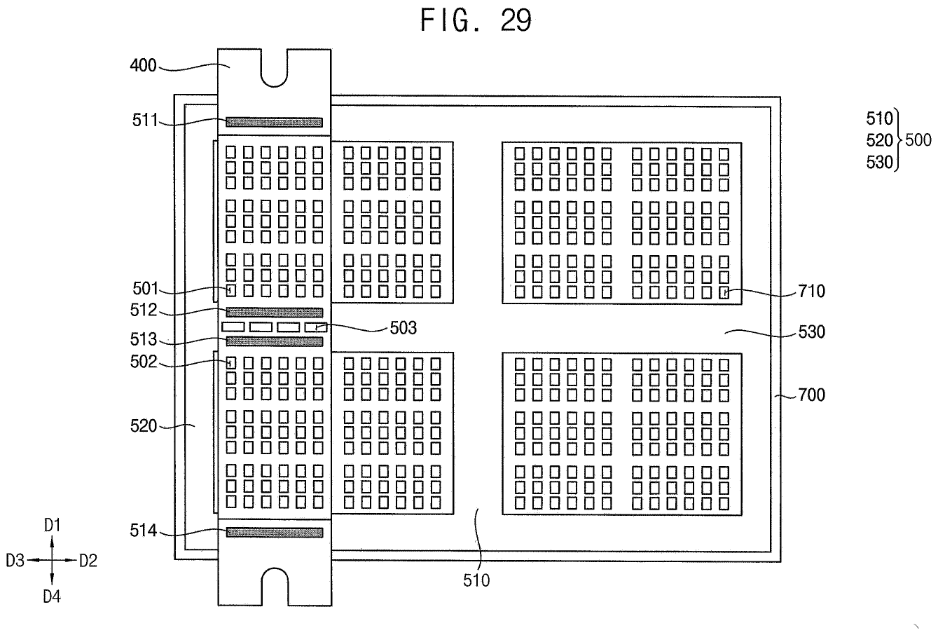

Referring to FIG. 29, the second fixing area 42 of the mask 400 may correspond to or overlap the second portion of the edge part 520 (e.g., the lower portion of the edge part 520) of the mask frame 500. After the second welding part 513 is provided or formed, the fourth welding part 514 may be provided or formed by welding a part of the second fixing area 42 of the mask 400 such as by using the CW laser. In an embodiment, for example, the fourth welding part 514 may extend along the second direction D2. In an embodiment, the fourth welding part 514 may be welded to the second portion of the edge part 520 so that the second fixing area 42 may be fixed to the second portion of the edge part 520.

Referring back to FIG. 21, a plurality of the masks 400 may be provided or formed on the mask frame 500 in the above-described manner. In an embodiment, the alignment adjustment process for each of the masks 400 may include first positioning the upper openings 501 provided or formed in the first deposition area 11 of each of the masks 400 to correspond to or overlap the sub-pixel areas 710 of the mother substrate 700 which are under the first deposition area 11, and second positioning of the lower openings 502 provided or formed in the second deposition area 12 of the mask 400 which has the upper openings 501 corresponding to the sub-pixel areas 710 which are under the first deposition area 11, to correspond to or overlap the sub-pixel areas 710 of the mother substrate 700 which are under the second deposition area 12.

Referring again to FIG. 1, after the masks 400 are provided on the mask frame 500, the first and second clamps may be separated from the first clamping area 31 and the second clamping area 32, respectively, and the first clamping area 31 and the second clamping area 32 may be removed from a remainder of the masks 400 such as through a mask cutting process. Accordingly, the mask assembly 100 shown in FIG. 1 may be provided. After the mask assembly 100 is provided, a deposition material (e.g., an organic light emitting material) may pass through the upper openings 501 and the lower openings 502 of the mask 400 so that the deposition material may be deposited on each of the sub-pixel areas 710 of the mother substrate 700.

One or more embodiment may be applied to various mask assemblies including a mask 400. One or more embodiment may be applied to a number of mask assemblies such as a metal mask assembly for depositing of an organic light emitting layer as a deposition pattern, a metal mask assembly for depositing of a thin film as a deposition pattern, etc.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. Therefore, it is to be understood that the foregoing is illustrative of various embodiments and is not to be construed as limited to the embodiments disclosed, and that modifications to the disclosed embodiments, as well as other embodiments, are intended to be included within the scope of the appended claims.

What is claimed is:

1. A mask assembly comprising:
a deposition mask frame comprising:
an edge portion including an upper portion and a lower portion opposing each other along a first direction, and
a support which is extended along a second direction crossing the first direction and is between the upper portion and the lower portion of the edge portion along the first direction; and
a deposition mask extending along the first direction and attachable to the deposition mask frame, the deposition mask including:
a pattern area corresponding to the support of the deposition mask frame, the pattern area including:
a first welded area at which the deposition mask is attachable to the support,
an alignment adjustment pattern which is adjacent to the first welded area along the first direction and corresponds to the support,
a first thickness of the deposition mask at the first welded area, and
a second thickness of the deposition mask at the alignment adjustment pattern which is less than the first thickness, and
a first deposition area including upper deposition openings of the deposition mask, the first deposition area between the upper portion and the support of the deposition mask frame.

2. The mask assembly of claim 1, wherein the alignment adjustment pattern which corresponds to the support of the deposition mask frame includes a groove.

3. The mask assembly of claim 2, wherein within the pattern area of the deposition mask, the groove is provided in plural including a plurality of grooves spaced apart from each other along the second direction.

4. The mask assembly of claim 1, wherein the alignment adjustment pattern which corresponds to the support of the deposition mask frame includes a through-opening extended through a thickness of the deposition mask at the pattern area.

5. The mask assembly of claim 4, wherein
the support of the deposition mask frame includes a top surface facing the deposition mask, and
the deposition mask which is attached to the deposition mask frame disposes the top surface of the support exposed to outside the deposition mask by the through-opening of the alignment adjustment pattern.

6. The mask assembly of claim 4, wherein
the deposition mask which is attached to the deposition mask frame disposes the support corresponding to the through-opening of the alignment adjustment pattern, and
the support of the deposition mask frame which corresponds to the through-opening of the alignment adjustment pattern blocks passage of a deposition material through the through-opening.

7. The mask assembly of claim 4, wherein within the pattern area of the deposition mask, the through-opening is provided in plural including a plurality of through-openings spaced apart from each other along the second direction.

8. The mask assembly of claim 1, wherein the pattern area of the deposition mask further includes a second welded area at which the deposition mask is attachable to the support of the deposition mask frame.

9. The mask assembly of claim 8, wherein within the pattern area of the deposition mask, the first welded area, the alignment adjustment pattern and the second welded area are in order along the first direction, the first welded area being closer to the first deposition area than the second welded area.

10. The mask assembly of claim 8, wherein the deposition mask which is attached to the deposition mask frame is attached to the support at both the first welded area and the second welded area and is unattached from the support at the alignment adjustment pattern.

11. The mask assembly of claim 1, wherein the deposition mask further includes a second deposition area including lower deposition openings of the deposition mask.

12. The mask assembly of claim 11, wherein within the deposition mask, the pattern area is between the first deposition area and the second deposition area along the first direction.

13. The mask assembly of claim 11, wherein the upper deposition openings and the lower deposition openings pass a deposition material therethrough.

14. The mask assembly of claim 11, wherein the deposition mask further includes:
a first end and a second end which opposes the first end along the first direction;
a first fixing area at the first end of the deposition mask;
a third welded area which is in the first fixing area and at which the deposition mask is attachable to the upper portion of the deposition mask frame;
a second fixing area at the second end of the deposition mask; and
a fourth welded area which is in the second fixing area and at which the deposition mask is attachable to the lower portion of the deposition mask frame.

15. The mask assembly of claim 14, wherein within the deposition mask, the first deposition area, the pattern area and the second deposition area are in order between the first fixing area and the second fixing area along the first direction.

16. The mask assembly of claim 15, wherein the first fixing area and the second fixing area of the deposition mask corresponds to the upper portion and the lower portion of the edge portion of the deposition mask frame, respectively.

17. The mask assembly of claim 15, wherein
the deposition mask which is attached to the deposition mask frame at the third welded area fixes a position of the upper deposition openings in the first deposition area relative to the deposition mask frame, and
the deposition mask which is attached to the deposition mask frame at the fourth welded area fixes a position of the lower deposition openings in the second deposition area relative to the deposition mask frame.

18. A method of providing a mask assembly, the method comprising:
providing a mask frame including:
an edge portion including an upper portion and a lower portion opposing each other along a first direction, and
a support which is extended along a second direction crossing the first direction and is between the upper portion and the lower portion of the edge portion along the first direction;
providing a mother substrate including a plurality of sub-pixel areas, facing the mask frame;
providing a deposition mask facing the mother substrate with the mask frame therebetween, the deposition mask which faces the mother substrate including in order along the first direction:
a first fixing area corresponding to the upper portion of the mask frame,
a first deposition area corresponding to upper sub-pixel areas of the mother substrate and including upper deposition openings,
a pattern area corresponding to the support of the mask frame and including an alignment adjustment pattern, wherein a thickness of the deposition mask at the alignment adjustment pattern is less than a thickness of the deposition mask at a remainder of the pattern area,
a second deposition area corresponding to lower sub-pixel areas of the mother substrate and including lower deposition openings,
a second fixing area corresponding to the lower portion of the mask frame, and
a clamping area extended from the second fixing area along the first direction and further than the lower portion of the edge portion of the mask frame;
providing both the first fixing area of the deposition mask fixed to the upper portion of the mask frame at a first welded area and the pattern area of the deposition mask fixed to the support of the mask frame at a second welded area; and
for the deposition mask which has the alignment adjustment pattern and is fixed to the mask frame at the first welded area and the second welded area, providing stretching of the clamping area in a direction different from the first direction, to align the lower deposition openings with the lower sub-pixel areas of the mother substrate.

19. The method of claim 18, further comprising:
the providing of both the first fixing area fixed to the upper portion of the mask frame at the first welded area and the pattern area fixed to the support of the mask frame at the second welded area aligns the upper deposition openings in the first deposition area of the deposition mask with the upper sub-pixel areas of the mother substrate; and
for the deposition mask having the lower deposition openings aligned with the lower sub-pixel areas of the mother substrate by the stretching of the clamping area, providing both the pattern area of the deposition mask further fixed to the support of the mask frame at a third welded area, and the second fixing area of the deposition mask fixed to the lower portion of the mask frame at a fourth welded area.

20. The method of claim 19, wherein within the pattern area of the deposition mask, the alignment adjustment pattern is between the second welded area and the third welded area along the first direction.
